(19) United States
(12) Patent Application Publication
(10) Pub. No.: US 2023/0306171 A1
(43) Pub. Date: Sep. 28, 2023

(54) DESIGNING TEST DEVICES USING AN INVERSE DESIGN PROCESS

(71) Applicant: X Development LLC, Mountain View, CA (US)

(72) Inventors: Cyril Bortolato, Mountain View, CA (US); Martin Schubert, Mountain View, CA (US)

(21) Appl. No.: 17/666,399

(22) Filed: Feb. 7, 2022

(51) Int. Cl. G06F 30/3308; G01B 11/00

(52) U.S. Cl. CPC G06F 30/3308; G01B 11/00

(57) ABSTRACT

Techniques for optimizing a test physical device for detecting variations in a fabrication process are disclosed. A computing system simulates fabrication of an initial design for the test physical device using at least a first and a second fabrication model to determine first and second structural parameters, respectively. The first fabrication model assumes a first value for a physical characteristic of outputs of the fabrication process, and the second fabrication model assumes a second value for the physical characteristic of outputs of the fabrication process. A first and second performance metric are obtained by simulating performance of the first and second structural parameters, respectively. A loss metric based on at least the first performance metric and the second performance metric is determined that penalizes performance metrics with similar values for dissimilar structural parameters. A gradient of the loss metric is backpropagated to generate an updated design.

### TECHNICAL FIELD

This disclosure relates generally to the design of physical devices for fabrication, and in particular but not exclusively, relates to photonic devices including but not limited to optical multiplexers and demultiplexers.

### BACKGROUND

Fiber-optic communication is typically employed to transmit information from one place to another via light that has been modulated to carry the information. For example, many telecommunication companies use optical fiber to transmit telephone signals, internet communication, and cable television signals. But the cost of deploying optical fibers for fiber-optic communication may be prohibitive. As such, techniques have been developed to more efficiently use the bandwidth available within a single optical fiber. Wavelength-division multiplexing is one such technique that bundles multiple optical carrier signals onto a single optical fiber using different wavelengths. Fabrication techniques used to create physical devices such as photonic devices for use in these contexts can create complex physical structures, but a fabricated physical device may differ from the design of the physical device due to specifics of the fabrication process as implemented by a particular fabrication system.

### BRIEF SUMMARY

In some embodiments, a non-transitory computer-readable medium having computer-executable instructions stored thereon is provided. The instructions, in response to execution by one or more processors of a computing system, cause the computing system to perform actions for optimizing a test physical device for detecting physical characteristics of outputs of a fabrication process. The actions include simulating, by the computing system, fabrication of an initial design for the test physical device using at least a first fabrication model to determine first structural parameters and a second fabrication model to determine second structural parameters, where the first fabrication model assumes a first value for a physical characteristic of outputs of the fabrication process, and where the second fabrication model assumes a second value for the physical characteristic of outputs of the fabrication process; obtaining at least a first performance metric by simulating performance of the first structural parameters; obtaining at least a second performance metric by simulating performance of the second structural parameters; determining a loss metric based on at least the first performance metric and the second performance metric, where the loss metric penalizes performance metrics with similar values for dissimilar structural parameters; and backpropagating a gradient of the loss metric to generate an updated design.

In some embodiments, a computer-implemented method for optimizing a test physical device for detecting variations in a fabrication process is provided. A computing system simulates fabrication of an initial design for the test physical device using at least a first fabrication model to determine first structural parameters and a second fabrication model to determine second structural parameters. The first fabrication model assumes a first value for a physical characteristic of outputs of the fabrication process, and the second fabrication model assumes a second value for the physical characteristic of outputs of the fabrication process. The computing system obtains at least a first performance metric by simulating performance of the first structural parameters. The computing system obtains at least a second performance metric by simulating performance of the second structural parameters. The computing system determines a loss metric based on at least the first performance metric and the second performance metric. The loss metric penalizes performance metrics with similar values for dissimilar structural parameters. The computing system backpropagates a gradient of the loss metric to generate an updated design.

In some embodiments, a method of determining a physical characteristic of physical devices fabricated by a fabrication system is provided. A design for a test physical device is provided to the fabrication system to fabricate the test physical device. Light is applied from a light source to an input port of the test physical device. Light output from an output port of the test physical device is measured to determine a performance metric. The performance metric is compared to simulated performance metrics associated with fabrication models that represent different physical characteristics. The physical characteristic is determined based on the comparison of the performance metric to the simulated performance metrics.

### BRIEF DESCRIPTION OF THE SEVERAL VIEWS OF THE DRAWINGS

Non-limiting and non-exhaustive embodiments of the invention are described with reference to the following figures, wherein like reference numerals refer to like parts throughout the various views unless otherwise specified. Not all instances of an element are necessarily labeled so as not to clutter the drawings where appropriate. The drawings are not necessarily to scale, emphasis instead being placed upon illustrating the principles being described. To easily identify the discussion of any particular element or act, the most significant digit or digits in a reference number refer to the figure number in which that element is first introduced.

FIG. 1 is a functional block diagram illustrating a non-limiting example embodiment of a system for optical communication between two optical communication devices via an optical signal, according to various aspects of the present disclosure.

FIG. 2A and FIG. 2B respectively illustrate a non-limiting example embodiment of a demultiplexer and multiplexer, according to various aspects of the present disclosure.

FIG. 2C illustrates a non-limiting example embodiment of a distinct wavelength channel of a multi-channel optical signal, according to various aspects of the present disclosure.

FIG. 3A - FIG. 3D illustrate different views of a non-limiting example embodiment of a photonic demultiplexer, according to various aspects of the present disclosure.

FIG. 4A and FIG. 4B illustrate a more detailed cross-sectional view of a dispersive region of a non-limiting example embodiment of a photonic demultiplexer, according to various aspects of the present disclosure.

FIG. 5 is a functional block diagram illustrating a non-limiting example embodiment of a system for generating a design of a photonic integrated circuit, according to various aspects of the present disclosure.

FIG. 6A illustrates a non-limiting example embodiment of a virtual prototype describing a photonic integrated circuit, according to various aspects of the present disclosure.

FIG. 6B illustrates a non-limiting example embodiment of an operational simulation of a photonic integrated circuit, according to various aspects of the present disclosure.

FIG. 6C illustrates a non-limiting example embodiment of an adjoint simulation within the virtual prototype by backpropagating a loss value, according to various aspects of the present disclosure.

FIG. 7 illustrates an aspect of the subject matter in accordance with one embodiment.

FIG. 8A illustrates a non-limiting example embodiment of a technique for using an inverse design process to determine a design that can be used to fabricate a physical device whose performance corresponds to physical characteristics of the as-fabricated design, according to various aspects of the present disclosure.

FIG. 8B is a chart illustrating the relationship between the update operation for the operational simulation and the adjoint simulation (e.g., backpropagation), in accordance with various aspects of the present disclosure.

FIG. 9A and FIG. 9B are a flowchart that illustrates a non-limiting example embodiment of a method of detecting characteristics of a fabrication process by measuring performance of a fabricated physical device, in accordance with various aspects of the present disclosure.

### DETAILED DESCRIPTION

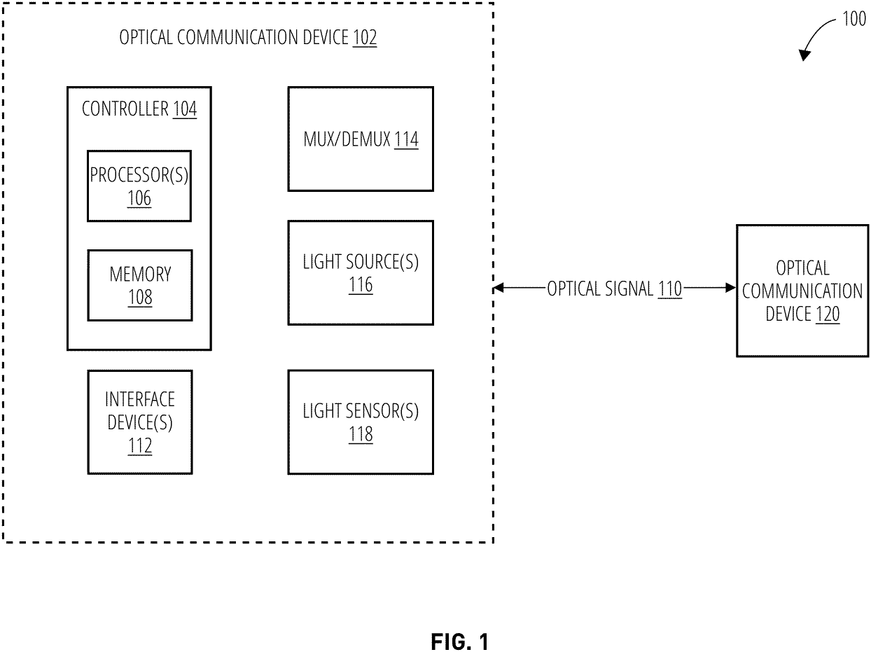

FIG. 1 is a functional block diagram illustrating a system 100 for optical communication (e.g., via wavelength division multiplexing or other techniques) between optical communication device 102 and optical communication device 120 via optical signal 110, in accordance with various aspects of the present disclosure. More generally, optical communication device 102 is configured to transmit information by modulating light from one or more light sources into a multi-channel optical signal 110 (e.g., a singular optical signal that includes a plurality of distinct wavelength channels) that is subsequently transmitted from optical communication device 102 to optical communication device 120 via an optical fiber, a light guide, a wave guide, or other photonic device. Optical communication device 120 receives the multi-channel optical signal 110 and demultiplexes each of the plurality of distinct wavelength channels from the multi-channel optical signal 110 to extract the transmitted information. It is appreciated that in some embodiments optical communication device 102 and optical communication device 120 may be distinct and separate devices (e.g., an optical transceiver or transmitter communicatively coupled via one or more optical fibers to a separate optical transceiver or receiver). However, in other embodiments, optical communication device 102 and optical communication device 120 may be part of a singular component or device (e.g., a smartphone, a tablet, a computer, optical device, or the like). For example, optical communication device 102 and optical communication device 120 may both be constituent components on a monolithic integrated circuit that are coupled to one another via a waveguide that is embedded within the monolithic integrated circuit and is adapted to carry optical signal 110 between optical communication device 102 and optical communication device 120 or otherwise transmit the optical signal between one place and another.

In the illustrated embodiment, optical communication device 102 includes a controller 104, one or more interface device(s) 112 (e.g., fiber optic couplers, light guides, waveguides, and the like), a multiplexer (mux), demultiplexer (demux), or combination thereof (MUX/DEMUX 114), one or more light source(s) 116 (e.g., light emitting diodes, lasers, and the like), and one or more light sensor(s) 118 (e.g., photodiodes, phototransistors, photoresistors, and the like) coupled to one another. The controller includes one or more processor(s) 106 (e.g., one or more central processing units, application specific circuits, field programmable gate arrays, or otherwise) and memory 108 (e.g., volatile memory such as DRAM and SAM, non-volatile memory such as ROM, flash memory, and the like). It is appreciated that optical communication device 120 may include the same or similar elements as optical communication device 102, which have been omitted for clarity.

Controller 104 orchestrates operation of optical communication device 102 for transmitting and/or receiving optical signal 110 (e.g., a multi-channel optical signal having a plurality of distinct wavelength channels or otherwise). Controller 104 includes software (e.g., instructions included in memory 108 coupled to processor 106) and/or hardware logic (e.g., application specific integrated circuits, field-programmable gate arrays, and the like) that when executed by controller 104 causes controller 104 and/or optical communication device 102 to perform operations.

In one embodiment, controller 104 may choreograph operations of optical communication device 102 to cause light source(s) 116 to generate a plurality of distinct wavelength channels that are multiplexed via MUX/DEMUX 114 into a multi-channel optical signal 110 that is subsequently transmitted to optical communication device 120 via interface device 112. In other words, light source(s) 116 may output light having different wavelengths (e.g., 1271 nm, 1291 nm, 1311 nm, 1331 nm, 1506 nm, 1514 nm, 1551 nm, 1571, or otherwise) that may be modulated or pulsed via controller 104 to generate a plurality of distinct wavelength channels representative of information. The plurality of distinct wavelength channels are subsequently combined or otherwise multiplexed via MUX/DEMUX 114 into a multi-channel optical signal 110 that is transmitted to optical communication device 120 via interface device 112. In the same or another embodiment, controller 104 may choreograph operations of optical communication device 102 to cause a plurality of distinct wavelength channels to be demultiplexed via MUX/DEMUX 114 from a multi-channel optical signal 110 that is received via interface device 112 from optical communication device 120.

It is appreciated that in some embodiments certain elements of optical communication device 102 and/or optical communication device 120 may have been omitted to avoid obscuring certain aspects of the disclosure. For example, optical communication device 102 and optical communication device 120 may include amplification circuitry, lenses, or components to facilitate transmitting and receiving optical signal 110. It is further appreciated that in some embodiments optical communication device 102 and/or optical communication device 120 may not necessarily include all elements illustrated in FIG. 1. For example, in one embodiment optical communication device 102 and/or optical communication device 120 are passive devices that operate as an intermediary device that may passively multiplex a plurality of distinct wavelength channels into a multi-channel optical signal 110 and/or demultiplex a plurality of distinct wavelength channels from a multi-channel optical signal 110.

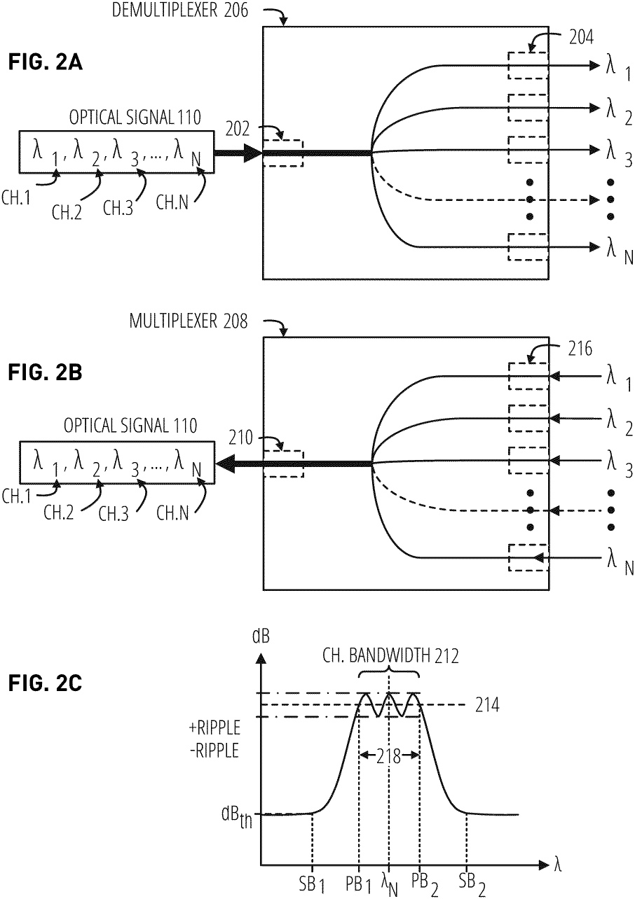

FIG. 2A and FIG. 2B respectively illustrate an example demultiplexer 206 and multiplexer 208, in accordance with various aspects of the present disclosure. Demultiplexer 206 and multiplexer 208 are possible embodiments of MUX/DEMUX 114 illustrated in FIG. 1, and which may be part of an integrated photonic circuit, silicon photonic device, or otherwise

As illustrated in FIG. 2A, demultiplexer 206 includes an input region 202 and a plurality of output regions 204. Demultiplexer 206 is configured to receive a multi-channel optical signal 110 that includes a plurality of distinct wavelength channels (e.g., Ch. 1, Ch. 2, Ch. 3, ...Ch. N, each having a center wavelength respectively corresponding to λ₁, λ₂, λ₃, ...λ_{N} ) via input region 202 (e.g., a waveguide that may correspond to interface device 112 illustrated in FIG. 1) to optically separate each of the plurality of distinct wavelength channels from the multi-channel optical signal 110 and respectively guide each of the plurality of distinct wavelength channels to a corresponding one of a plurality of output regions 204 (e.g., a plurality of waveguides that may correspond to interface device(s) 112 illustrated in FIG. 1). More specifically, in the illustrated embodiment, each of the output regions 204 receives a portion of the multi-channel optical signal that corresponds to, or is otherwise representative of, one of the plurality of distinct wavelength channels that may be output as plurality of optical signals (e.g., λ₁, λ₂, λ₃, ...λ_{N}). Each output region 204 may be coupled to a respective light sensor (e.g., corresponding to light sensor(s) 118 illustrated in FIG. 1), which may be utilized to convert the optical signals demultiplexed from the multi-channel optical signal 110 into electrical signals for further processing.

In the illustrated embodiment of FIG. 2B, multiplexer 208 includes a plurality of input regions 216 and an output region 210. Multiplexer 208 is configured to receive a plurality of distinct optical signals (e.g., λ₁, λ₂, λ₃, ...λ_{N}), each at a respective one of the plurality of input regions 216 (e.g., a plurality of waveguides that may correspond to interface device(s) 112 illustrated in FIG. 1). Multiplexer 208 is structured or otherwise configured to optically combine (i.e., multiplex) each of the plurality of distinct wavelength channels into a multi-channel optical signal 110 that is guided to output region 210 (e.g., a waveguide that may correspond to interface device 112 illustrated in FIG. 1). It is appreciated that in some embodiments, demultiplexer 206 illustrated in FIG. 2A and multiplexer 208 illustrated in FIG. 2B may be bidirectional such that each device may function as both a demultiplexer and multiplexer.

FIG. 2C illustrates an example distinct wavelength channel of a multi-channel optical signal (e.g., Ch. N is multi-channel optical signal 110 illustrated in FIG. 1, FIG. 2A, and FIG. 2B), in accordance with various aspects of the present disclosure. The example channel may be representative of an individual channel included in a plurality of distinct wavelength channels of the multi-channel optical signal that may be demultiplexed and/or multiplexed by demultiplexer 206 of FIG. 2A and/or multiplexer 208 of FIG. 2B. Each of the distinct wavelength channels may have different center wavelengths (λ_{N}) including at least one of 1271 nm, 1291 nm, 1311 nm, 1331 nm, 1506 nm, 1514 nm, 1551 nm, or 1571 nm, or otherwise. In the illustrated embodiment of FIG. 2C, the distinct wavelength channel has a channel bandwidth 212 of approximately 13 nm wide. However, in other embodiments the channel bandwidth may be different than 13 nm wide. Rather, the channel bandwidth may be considered a configurable parameter that is dependent upon the structure of MUX/DEMUX 114 of FIG. 1, demultiplexer 206 of FIG. 2A, and/or multiplexer 208 of FIG. 2B. For example, in some embodiments each of the plurality of distinct wavelength channels may share a common bandwidth that may correspond to 13 nm or otherwise. Referring back to FIG. 2C, the channel bandwidth 212 may be defined as the width of a passband region 218 (i.e., the region defined as being between PB₁ and PB₂). The passband region 218 may represent an approximate power transmission of a demultiplexer or multiplexer. It is appreciated that in some embodiments the passband region 218 may include ripple as illustrated in FIG. 2C, which corresponds to fluctuations within the passband region 218. In one or more embodiments, the ripple within the passband region around a central value 214 may be +/- 2 dB or less, +/- 1 dB or less, +/- 0.5 dB or less, or otherwise. In some embodiments, the channel bandwidth 212 may be defined by the passband region 218. In other embodiments, the channel bandwidth 212 may be defined as the measured power above a threshold (e.g., dBₜₕ). For example, demultiplexer 206 illustrated in FIG. 2A may optically separate channel N from multi-channel optical signal 110 and have a corresponding channel bandwidth for channel N equivalent to the range of wavelengths above a threshold value that are transmitted to the output region 204 mapped to channel N (i.e., λ_{N}). In the same or other embodiments, isolation of the channel (i.e., defined by channel bandwidth 212) may also be considered when optimizing the design. The isolation may be defined as a ratio between the passband region 218 and the stopband regions (e.g., regions less than SB₁ and greater than SB₂). It is further appreciated that transition band regions (e.g., a first transition region between SB₁ and PB₁ and a second transition region between PB₂ and SB₂) are exemplary and may be exaggerated for the purposes of illustration. In some embodiments, optimization of the design of the photonic demultiplexer may also include a target metric for a slope, width, or the like of the transition band regions.

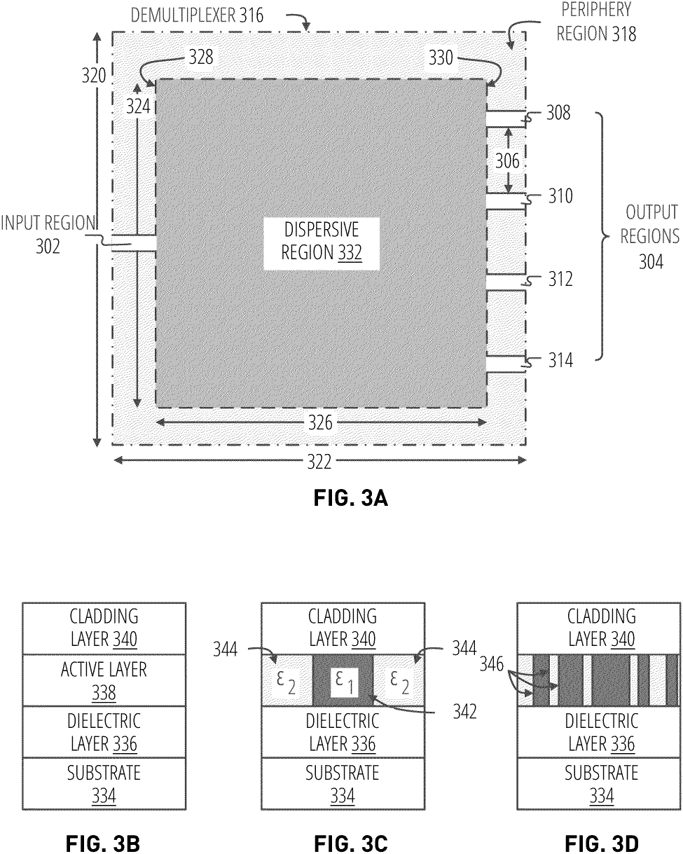

FIG. 3A - FIG. 3D illustrate different views of an example photonic demultiplexer, in accordance with an embodiment of the present disclosure. Photonic demultiplexer 316 is one possible implementation of MUX/DEMUX 114 illustrated in FIG. 1 and demultiplexer 206 illustrated in FIG. 2A. It is further appreciated that while discussion henceforth may be directed towards photonic integrated circuits capable of demultiplexing a plurality of distinct wavelength channels from a multi-channel optical signal, that in other embodiments, a demultiplexer (e.g., demultiplexer 316) may also or alternatively be capable of multiplexing a plurality of distinct wavelength channels into a multi-channel optical signal, in accordance with embodiments of the present disclosure.

FIG. 3A illustrates a cross-sectional view of demultiplexer 316 along a lateral plane within an active layer defined by a width 320 and a length 322 of the demultiplexer 316. As illustrated, demultiplexer 316 includes an input region 302 (e.g., comparable to input region 202 illustrated in FIG. 2A), a plurality of output regions 304 (e.g., comparable to plurality of output regions 204 illustrated in FIG. 2A), and a dispersive region optically disposed between the input region 302 and plurality of output regions 304. The input region 302 and plurality of output regions 304 (e.g., output region 308, output region 310, output region 312, and output region 314) may each be waveguides (e.g., slab waveguide, strip waveguide, slot waveguide, or the like) capable of propagating light along the path of the waveguide. The dispersive region 332 includes a first material and a second material (see, e.g., FIG. 3D) inhomogeneously interspersed to form a plurality of interfaces that each correspond to a change in refractive index of the dispersive region 332 and collectively structure the dispersive region 332 to optically separate each of a plurality of distinct wavelength channels (e.g., Ch. 1, Ch. 2, Ch. 3, ... Ch. N illustrated in FIG. 2A) from a multi-channel optical signal (e.g., optical signal 110 illustrated in FIG. 2A) and respectively guide each of the plurality of distinct wavelength channels to a corresponding one of the plurality of output regions 304 when the input region 302 receives the multi-channel optical signal. In other words, input region 302 is adapted to receive the multi-channel optical signal including a plurality of distinct wavelength channels and the plurality of output regions 304 are adapted to each receive a corresponding one of the plurality of distinct wavelength channels demultiplexed from the multi-channel optical signal via dispersive region 332.

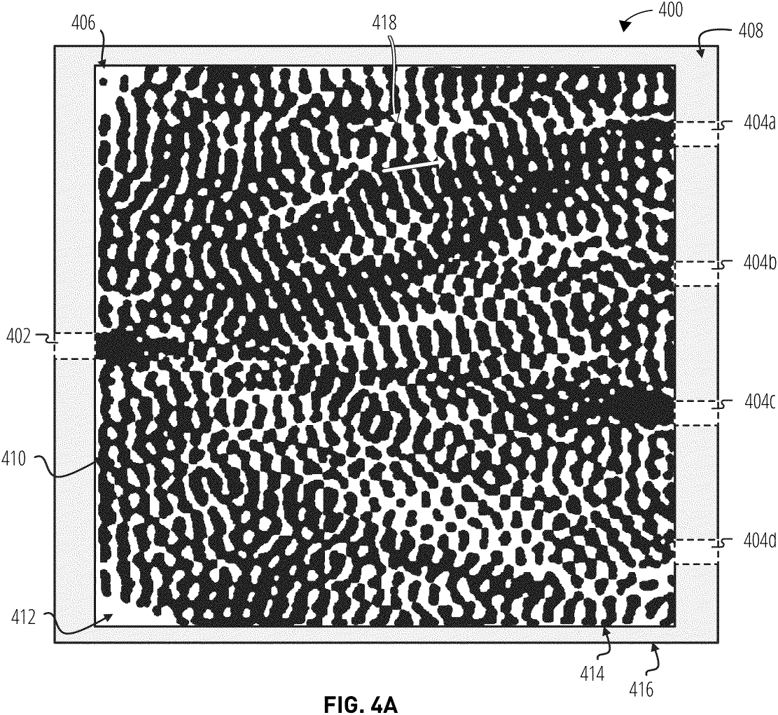

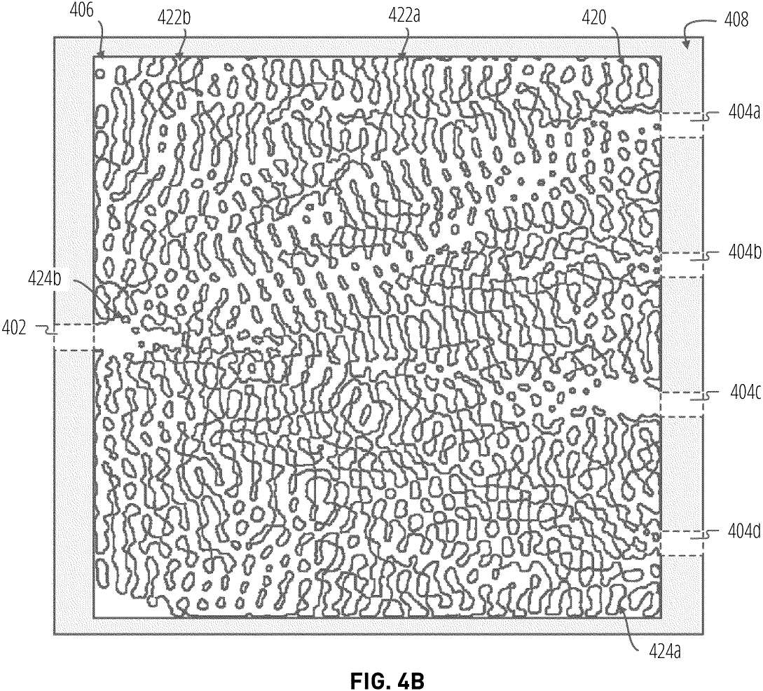

As illustrated in FIG. 3A, and more clearly shown in FIG. 3D and FIG. 4A-FIG. 4B, the shape and arrangement of the first and second material that are inhomogeneously interspersed create a plurality of interfaces that collectively form a material interface pattern along a cross-sectional area of dispersive region 332 that is at least partially surrounded by a periphery region 318 that includes the second material. In some embodiments periphery region 318 has a substantially homogeneous composition that includes the second material. In the illustrated embodiment, dispersive region 332 includes a first side 328 and a second side 330 that each interface with an inner boundary (i.e., the unlabeled dashed line of periphery region 318 disposed between dispersive region 332 and dashed-dotted line corresponding to an outer boundary of periphery region 318). First side 328 and second side 330 are disposed correspond to opposing sides of dispersive region 332. Input region 302 is disposed proximate to first side 328 (e.g., one side of input region 302 abuts first side 328 of dispersive region 332) while each of the plurality of output region 304 are disposed proximate to second side 330 (e.g., one side of each of the plurality of output region 304 abuts second side 330 of dispersive region 332).

In the illustrated embodiment each of the plurality of output regions 304 are parallel to each other one of the plurality of output region 304. However, in other embodiments the plurality of output regions 304 may not be parallel to one another or even disposed on the same side (e.g., one or more of the plurality of output regions 304 and/or input region 302 may be disposed proximate to sides of dispersive region 332 that are adjacent to first side 328 and/or second side 330). In some embodiments adjacent ones of the plurality of output regions are separated from each other by a common separation distance when the plurality of output regions includes at least three output regions. For example, as illustrated adjacent output region 308 and output region 310 are separated from one another by distance 306, which may be common to the separation distance between other pairs of adjacent output regions.

As illustrated in the embodiment of FIG. 3A, demultiplexer 316 includes four output regions 304 (e.g., output region 308, output region 310, output region 312, output region 314) that are each respectively mapped (i.e., by virtue of the structure of dispersive region 332) to a respective one of four channels included in a plurality of distinct wavelength channels. More specifically, the plurality of interfaces of dispersive region 332, defined by the inhomogeneous interspersion of a first material and a second material, form a material interface pattern along a cross-sectional area of the dispersive region 332 (e.g., as illustrated in FIG. 3A, FIG. 4A, or FIG. 4B) to cause the dispersive region 332 to optically separate each of the four channels from the multi-channel optical signal and route each of the four channels to a respective one of the four output regions 304 when the input region 302 regions the multi-channel optical signal.

It is noted that the first material and second material of dispersive region 332 are arranged and shaped within the dispersive region such that the material interface pattern is substantially proportional to a design obtainable with an inverse design process, which will be discussed in greater detail later in the present disclosure. More specifically, in some embodiments, the inverse design process may include iterative gradient-based optimization of a design based at least in part on a loss function that incorporates a performance loss (e.g., to enforce functionality) and a fabrication loss (e.g., to enforce fabricability and binarization of a first material and a second material) that is reduced or otherwise adjusted via iterative gradient-based optimization to generate the design. In the same or other embodiments, other optimization techniques may be used instead of, or jointly with, gradient-based optimization. Advantageously, this allows for optimization of a near unlimited number of design parameters to achieve functionality and performance within a predetermined area that may not have been possible with conventional design techniques.

For example, in one embodiment dispersive region 332 is structured to optically separate each of the four channels from the multi-channel optical signal within a predetermined area of 35 µm × 35 µm (e.g., as defined by width 324 and length 326 of dispersive region 332) when the input region 302 receives the multi-channel optical signal. In the same or another embodiment, the dispersive region is structured to accommodate a common bandwidth for each of the four channels, each of the four channels having different center wavelengths. In one embodiment the common bandwidth is approximately 13 nm wide and the different center wavelengths is selected from a group consisting of 1271 nm, 1291 nm, 1311 nm, 1331 nm, 1506 nm, 1514 nm, 1551 nm, and 1571 nm. In some embodiments, the entire structure of demultiplexer 316 (e.g., including input region 302, periphery region 318, dispersive region 332, and plurality of output regions 304) fits within a predetermined area (e.g., as defined by width 320 and length 322). In one embodiment the predetermined area is 35 µm × 35 µm. It is appreciated that in other embodiments dispersive region 332 and/or demultiplexer 316 fits within other areas greater than or less than 35 µm × 35 µm, which may result in changes to the structure of dispersive region 332 (e.g., the arrangement and shape of the first and second material) and/or other components of demultiplexer 316.

In the same or other embodiments the dispersive region is structured to have a power transmission of -2 dB or greater from the input region 302, through the dispersive region 332, and to the corresponding one of the plurality of output regions 304 for a given wavelength within one of the plurality of distinct wavelength channels. For example, if channel 1 of a multi-channel optical signal is mapped to output region 308, then when demultiplexer 316 receives the multi-channel optical signal at input region 302 the dispersive region 332 will optically separate channel 1 from the multi-channel optical signal and guide a portion of the multi-channel optical signal corresponding to channel 1 to output region 308 with a power transmission of -2 dB or greater. In the same or another embodiment, dispersive region 332 is structured such that an adverse power transmission (i.e., isolation) for the given wavelength from the input region to any of the plurality of output regions other than the corresponding one of the plurality of output regions is -30 dB or less, -22 dB or less, or otherwise. For example, if channel 1 of a multi-channel optical signal is mapped to output region 308, then the adverse power transmission from input region 302 to any other one of the plurality of output regions (e.g., output region 310, output region 312, output region 314) other than the corresponding one of the plurality of output regions (e.g., output region 308) is -30 dB or less, -22 dB or less, or otherwise. In some embodiments, a maximum power reflection from demultiplexer 316 of an input signal (e.g., a multi-channel optical signal) received at an input region (e.g., input region 302) is reflected back to the input region by dispersive region 332 or otherwise is -40 dB or less, -20 dB or less, -8 dB or less, or otherwise. It is appreciated that in other embodiments the power transmission, adverse power transmission, maximum power, or other performance characteristics may be different than the respective values discussed herein, but the structure of dispersive region 332 may change due to the intrinsic relationship between structure, functionality, and performance of demultiplexer 316.

FIG. 3B illustrates a vertical schematic or stack of various layers that are included in the illustrated embodiment of demultiplexer 316. However, it is appreciated that the illustrated embodiment is not exhaustive and that certain features or elements may be omitted to avoid obscuring certain aspects of the invention. In the illustrated embodiment, demultiplexer 316 includes substrate 334, dielectric layer 336, active layer 338 (e.g., as shown in the cross-sectional illustration of FIG. 3A), and a cladding layer 340. In some embodiments, demultiplexer 316 may be, in part or otherwise, a photonic integrated circuit or silicon photonic device that is compatible with conventional fabrication techniques (e.g., lithographic techniques such as photolithographic, electronbeam lithography and the like, sputtering, thermal evaporation, physical and chemical vapor deposition, and the like).

In one embodiment a silicon on insulator (SOI) wafer may be initially provided that includes a support substrate (e.g., a silicon substrate) that corresponds to substrate 334, a silicon dioxide dielectric layer that corresponds to dielectric layer 336, a silicon layer (e.g., intrinsic, doped, or otherwise), and a oxide layer (e.g., intrinsic, grown, or otherwise). In one embodiment, the silicon in the active layer 338 may be etched selectively by lithographically creating a pattern on the SOI wafer that is transferred to SOI wafer via a dry etch process (e.g., via a photoresist mask or other hard mask) to remove portions of the silicon. The silicon may be etched all the way down to dielectric layer 336 to form voids that may subsequently be backfilled with silicon dioxide that is subsequently encapsulated with silicon dioxide to form cladding layer 340. In one embodiment, there may be several etch depths including a full etch depth of the silicon to obtain the targeted structure. In one embodiment, the silicon may be 206 nm thick and thus the full etch depth may be 206 nm. In some embodiments, this may be a two-step encapsulation process in which two silicon dioxide depositions are performed with an intermediate chemical mechanical planarization used to yield a planar surface.

FIG. 3C illustrates a more detailed view of active layer 338 (relative to FIG. 3B) taken along a portion of periphery region 318 that includes input region 302 of FIG. 3A. In the illustrated embodiment, active layer 338 includes a first material 342 with a refractive index of ε₁ and a second material 344 with a refractive index of ε₂ that is different from ε₁. Homogenous regions of the first material 342 and the second material 344 may form waveguides or portions of waveguides that correspond to input region 302 and plurality of output region 304 as illustrated in FIG. 3A and FIG. 3C.

FIG. 3D illustrates a more detailed view of active layer 338 (relative to FIG. 3B) taken along dispersive region 332. As described previously, active layer 338 includes a first material 342 (e.g., silicon) and a second material 344 (e.g., silicon dioxide) that are inhomogeneously interspersed to form a plurality of interfaces 346 that collectively form a material interface pattern. Each of the plurality of interfaces 346 that form the interface pattern correspond to a change in refractive index of dispersive region 332 to structure the dispersive region (i.e., the shape and arrangement of first material 342 and second material 344) to provide, at least in part, the functionality of demultiplexer 316 (i.e., optical separation of the plurality of distinct wavelength channels from the multi-channel optical signal and respective guidance of each of the plurality of distinct wavelength channels to the corresponding one of the plurality of output regions 304 when the input region 302 receives the multi-channel optical signal).

It is appreciated that in the illustrated embodiments of demultiplexer 316 as shown in FIG. 3A - FIG. 3D, the change in refractive index is shown as being vertically consistent (i.e., the first material 342 and second material 344 form interfaces that are substantially vertical or perpendicular to a lateral plane or cross-section of demultiplexer 316. However, in the same or other embodiments, the plurality of interfaces (e.g., interfaces 346 illustrated in FIG. 3D) may not be substantially perpendicular with the lateral plane or cross-section of demultiplexer 316.

FIG. 4A illustrates a more detailed cross-sectional view of a dispersive region of example photonic demultiplexer 400, in accordance with an embodiment of the present disclosure. FIG. 4B illustrates a more detailed view of an interface pattern formed by the shape and arrangement of a first material 410 and a second material 412 for the dispersive region of the photonic demultiplexer 400 of FIG. 4A. Photonic demultiplexer 400 is one possible implementation of MUX/DEMUX 114 illustrated in FIG. 1, demultiplexer 206 illustrated in FIG. 2A, and demultiplexer 316 illustrated in FIG. 3A-FIG. 3D.

As illustrated in FIG. 4A and FIG. 4B, photonic demultiplexer 400 includes an input region 402, a plurality of output regions 404a-404d, and a dispersive region 406 optically disposed between input region 402 and plurality of output regions 404a-404d. Dispersive region 406 is surrounded, at least in part, by a peripheral region 408 that includes an inner boundary 414 and an outer boundary 416. It is appreciated that like named or labeled elements of photonic demultiplexer 400 may similarly correspond to like named or labeled elements of other demultiplexers described in embodiments of the present disclosure.

The first material 410 (i.e., black colored regions within dispersive region 406) and second material 412 (i.e., white colored regions within dispersive region 406) of photonic demultiplexer 400 are inhomogeneously interspersed to create a plurality of interfaces that collectively form material interface pattern 420 as illustrated in FIG. 4B. More specifically, an inverse design process that utilizes iterative gradient-based optimization, Markov Chain Monte Carlo optimization, or other optimization techniques combined with first principles simulations to generate a design that is substantially replicated by dispersive region 406 within a proportional or scaled manner such that photonic demultiplexer 400 provides the desired functionality. In the illustrated embodiment, dispersive region 406 is structured to optically separate each of a plurality of distinct wavelength channels from a multi-channel optical signal and respectively guide each of the plurality of distinct wavelength channels to a corresponding one of the plurality of output regions 404a-404d when the input region 402 receives the multi-channel optical signal. More specifically, the plurality of output regions 404a-404d are respectively mapped to wavelength channels having center wavelengths correspond to 1271 nm, 1291 nm, 1311 nm, and 1331 nm. In another embodiment, output regions 404a-404d are respectfully mapped to wavelength channels having center wavelengths that correspond to 1506 nm, 1514 nm, 1551 nm, and 1571 nm.

As illustrated in FIG. 4B, material interface pattern 420, which is defined by the black lines within dispersive region 406 and corresponds to a change in refractive index within dispersive region 406, includes a plurality of protrusions 422a-422b. A first protrusion 422a is formed of the first material 410 and extends from peripheral region 408 into dispersive region 406. Similarly, a second protrusion 422b is formed of the second material 412 and extends from peripheral region 408 into dispersive region 406. Further illustrated in FIG. 4B, dispersive region 406 includes a plurality of islands 424a-424b formed of either the first material 410 or the second material 412. The plurality of islands 424a-424b include a first island 424a that is formed of the first material 410 and is surrounded by the second material 412. The plurality of islands 424a-424b also includes a second island 424b that is formed of the second material 412 and is surrounded by the first material 410.

In some embodiments, material interface pattern 420 includes one or more dendritic shapes, wherein each of the one or more dendritic shapes are defined as a branched structure formed from first material 410 or second material 412 and having a width that alternates between increasing and decreasing in size along a corresponding direction. Referring back to FIG. 4A, for clarity, dendritic structure 418 is labeled with a white arrow having a black border. As can be seen, the width of dendritic structure 418 alternatively increases and decreases in size along a corresponding direction (i.e., the white labeled arrow overlaying a length of dendritic structure 418) to create a branched structure. It is appreciated that in other embodiments there may be no protrusions, there may be no islands, there may be no dendritic structures, or there may be any number, including zero, of protrusions, islands of any material included in the dispersive region 406, dendritic structures, or a combination thereof.

In some embodiments, the inverse design process includes a fabrication loss that enforces a minimum feature size, for example, to ensure fabricability of the design. In the illustrated embodiment of photonic demultiplexer 400 illustrated in FIG. 4A and FIG. 4B, material interface pattern 420 is shaped to enforce a minimum feature size within dispersive region 406 such that the plurality of interfaces within the cross-sectional area formed with first material 410 and second material 412 do not have a radius of curvature with a magnitude of less than a threshold size. For example, if the minimum feature size is 150 nm, the radius of curvature for any of the plurality of interfaces have a magnitude of less than the threshold size, which corresponds the inverse of half the minimum feature size (i.e., 1/75 nm⁻¹). Enforcement of such a minimum feature size prevents the inverse design process from generating designs that are not fabricable by considering manufacturing constraints, limitations, and/or yield. In the same or other embodiments, different or additional checks on metrics related to fabricability may be utilized to enforce a minimum width or spacing as a minimum feature size.

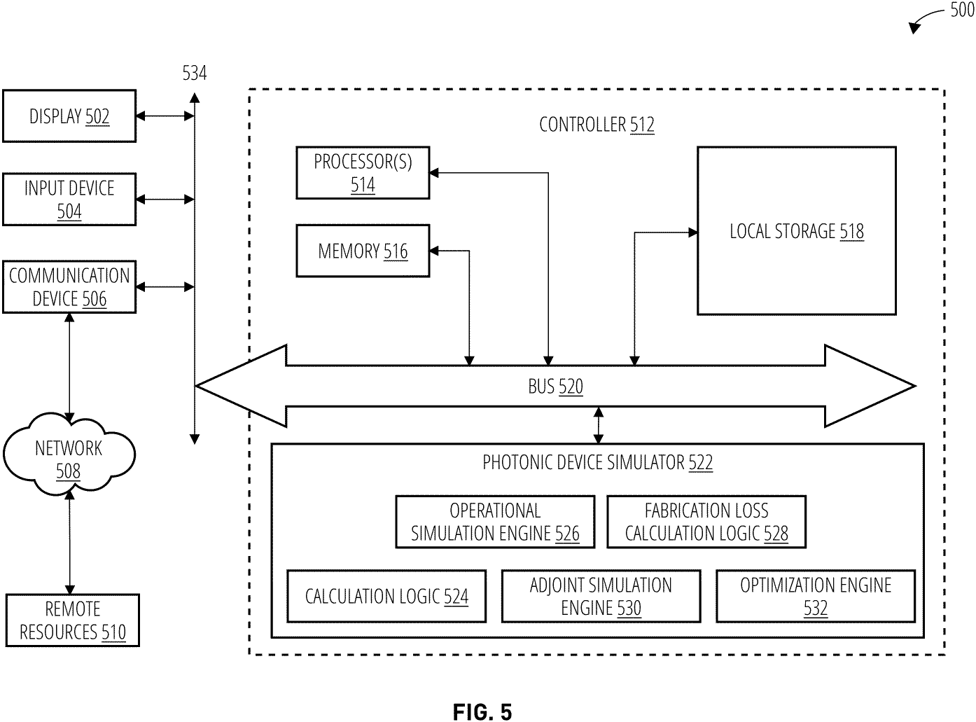

FIG. 5 is a functional block diagram illustrating a design optimization system 500 for generating a design of a photonic integrated circuit (i.e., photonic device), in accordance with an embodiment of the disclosure. Design optimization system 500 may be utilized to perform an inverse design process that generates a design with iterative gradient-based optimization that takes into consideration the underlying physics that govern the operation of the photonic integrated circuit. More specifically, design optimization system 500 is a design tool that may be utilized to optimize structural parameters (e.g., shape and arrangement of a first material and a second material within the dispersive region of the embodiments described in the present disclosure) of photonic integrated circuits based on first-principles simulations (e.g., electromagnetic simulations to determine a field response of the photonic device to an excitation source) and iterative gradient-based optimization. In other words, design optimization system 500 may provide a design obtained via the inverse design process that is substantially replicated (i.e., proportionally scaled) by dispersive region 332 and dispersive region 406 of demultiplexer 316 and photonic demultiplexer 400 illustrated in FIG. 3A and FIG. 4A, respectively.

As illustrated, design optimization system 500 includes controller 512, display 502, input device(s) 504, communication device(s) 506, network 508, remote resources 510, bus 534, and bus 520. Controller 512 includes processor 514, memory 516, local storage 518, and photonic device simulator 522. Photonic device simulator 522 includes operational simulation engine 526, fabrication loss calculation logic 528, calculation logic 524, adjoint simulation engine 530, and optimization engine 532. It is appreciated that in some embodiments, controller 512 may be a distributed system.

Controller 512 is coupled to display 502 (e.g., a light emitting diode display, a liquid crystal display, and the like) coupled to bus 534 through bus 520 for displaying information to a user utilizing design optimization system 500 to optimize structural parameters of the photonic device (i.e., demultiplexer). Input device 504 is coupled to bus 534 through bus 520 for communicating information and command selections to processor 514. Input device 504 may include a mouse, trackball, keyboard, stylus, or other computer peripheral, to facilitate an interaction between the user and controller 512. In response, controller 512 may provide verification of the interaction through display 502.

Another device, which may optionally be coupled to controller 512, is one or more communication device(s) 506 for accessing remote resources 510 of a distributed system via network 508. Communication device 506 may include any of a number of networking peripheral devices such as those used for coupling to an Ethernet, Internet, or wide area network, and the like. Communication device 506 may further include a mechanism that provides connectivity between controller 512 and the outside world. Note that any or all of the components of design optimization system 500 illustrated in FIG. 5 and associated hardware may be used in various embodiments of the present disclosure. The remote resources 510 may be part of a distributed system and include any number of processors, memory, and other resources for optimizing the structural parameters of the photonic device.

Controller 512 orchestrates operation of design optimization system 500 for optimizing structural parameters of the photonic device. Processor 514 (e.g., one or more central processing units, graphics processing units, and/or tensor processing units, etc.), memory 516 (e.g., volatile memory such as DRAM and SRAM, non-volatile memory such as ROM, flash memory, and the like), local storage 518 (e.g., magnetic memory such as computer disk drives), and the photonic device simulator 522 are coupled to each other through bus 520. Controller 512 includes software (e.g., instructions included in memory 516 coupled to processor 514) and/or hardware logic (e.g., application specific integrated circuits, field-programmable gate arrays, and the like) that when executed by controller 512 causes controller 512 or design optimization system 500 to perform operations. The operations may be based on instructions stored within any one of, or a combination of, memory 516, local storage 518, physical device simulator 522, and remote resources 510 accessed through network 508.

In the illustrated embodiment, the components of photonic device simulator 522 are utilized to optimize structural parameters of the photonic device (e.g., MUX/DEMUX 114 of FIG. 1, demultiplexer 206 of FIG. 2A, multiplexer 208 of FIG. 2B, demultiplexer 316 of FIG. 3A-FIG. 3D, and photonic demultiplexer 400 of FIG. 4A-FIG. 4B). In some embodiments, design optimization system 500 may optimize the structural parameters of the photonic device via, inter alia, simulations (e.g., operational and adjoint simulations) that utilize a finite-difference time-domain (FDTD) method, a finite-difference frequency-domain (FDFD) method, or any other suitable technique to model the field response (e.g., electric and magnetic fields within the photonic device). The operational simulation engine 526 provides instructions for performing an electromagnetic simulation of the photonic device operating in response to an excitation source within a virtual prototype. In particular, the operational simulation determines a field response of the virtual prototype (and thus the photonic device, which is described by the virtual prototype) in response to the excitation source for determining a performance metric of the physical device (e.g., based off an initial description or input design of the photonic device that describes the structural parameters of the photonic device within the virtual prototype with a plurality of voxels). The structural parameters may correspond, for example, to the specific design, material compositions, dimensions, and the like of the physical device. Fabrication loss calculation logic 528 provides instructions for determining a fabrication loss, which is utilized to enforce a minimum feature size to ensure fabricability. In some embodiments, the fabrication loss is also used to enforce binarization of the design (i.e., such that the photonic device includes a first material and a second material that are interspersed to form a plurality of interfaces). Calculation logic 524 computes a loss metric determined via a loss function that incorporates a performance loss, based on the performance metric, and the fabrication loss. Adjoint simulation engine 530 is utilized in conjunction with the operational simulation engine 526 to perform an adjoint simulation of the photonic device to backpropagate the loss metric through the virtual prototype via the loss function to determine how changes in the structural parameters of the photonic device influence the loss metric (i.e., the gradient of the loss function with respect to the structural parameters, otherwise known as a sensitivity map). Optimization engine 532 is utilized to update the structural parameters of the photonic device to reduce the loss metric and generate a revised description (i.e., revising the design) of the photonic device.

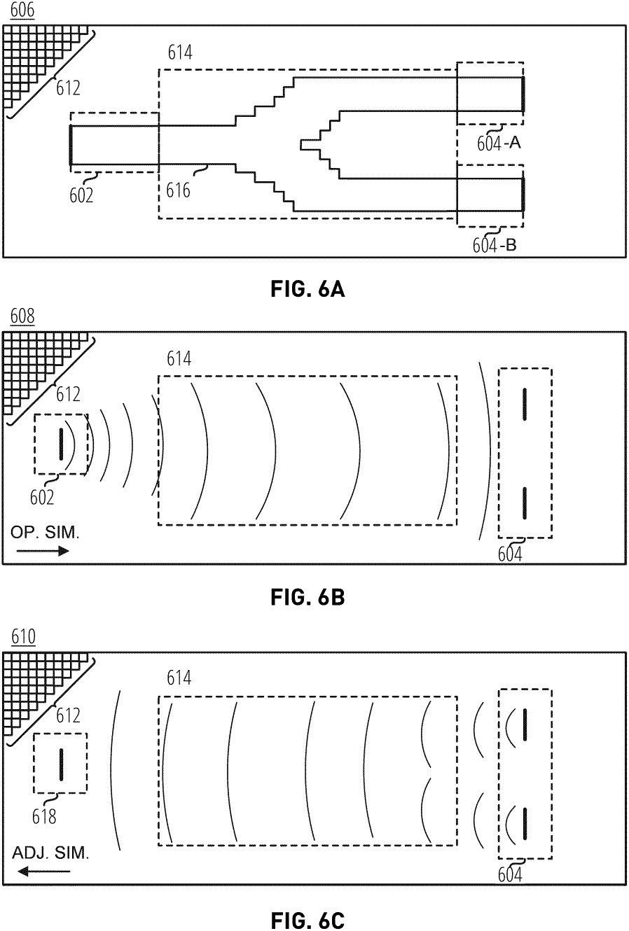

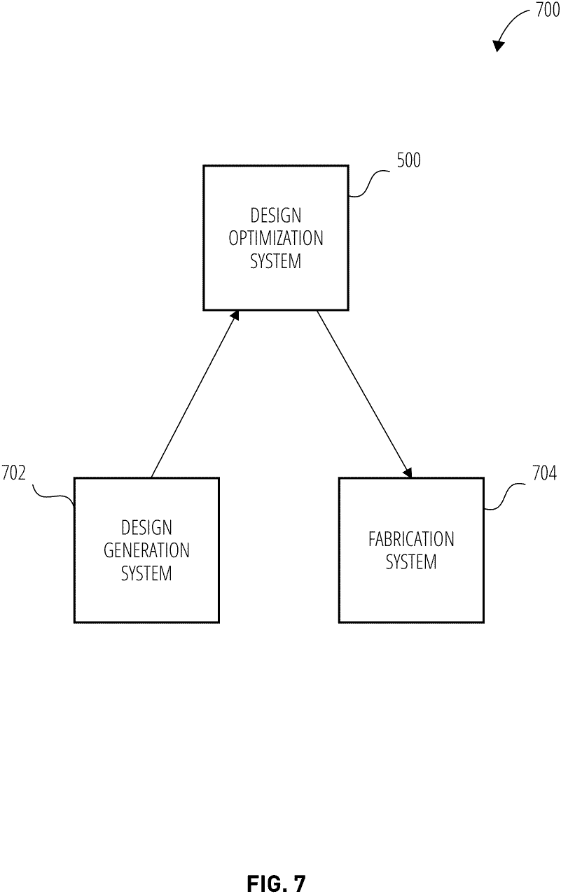

FIG. 6A-FIG. 6C respectively illustrate non-limiting example embodiments of an initial set up of a virtual prototype 606 describing a photonic device, performing an operational simulation of the photonic device in response to an excitation source within the virtual prototype 608, and performing an adjoint simulation of the photonic device within the virtual prototype 610 according to various aspects of the present disclosure. The initial set up of the virtual prototype, 1-dimensional representation of the virtual prototype, operational simulation of the physical device, and adjoint simulation of the physical device may be implemented with design optimization system 500 illustrated in FIG. 5.

As illustrated in FIG. 6A-FIG. 6C, the virtual prototype is represented in two dimensions. However, it is appreciated that other dimensionality (e.g., 3-dimensional space) may also be used to describe the virtual prototype and the photonic device. In some embodiments, optimization of structural parameters of the photonic device illustrated in FIG. 6A-FIG. 6C may be achieved via an inverse design process including, inter alia, simulations (e.g., operational simulations and adjoint simulations) that utilize a finite-difference time-domain (FDTD) method, a finite-difference frequency-domain (FDFD) method, or any other suitable technique to model the field response (e.g., electric and magnetic field) to an excitation source.

FIG. 6A illustrates a demonstrative virtual prototype 606 describing a photonic integrated circuit (i.e., a photonic device such as a waveguide, demultiplexer, and the like), in accordance with a non-limiting example embodiment of the present disclosure. More specifically, in response to receiving an initial description of a photonic device defined by one or more structural parameters (e.g., an input design), a system (e.g., design optimization system 500 of FIG. 5) configures a virtual prototype 606 to be representative of the photonic device. As illustrated, the virtual prototype 606 (and subsequently the photonic device) is described by a plurality of voxels 612, which represent individual elements (i.e., discretized) of the two-dimensional (or other dimensionality) space. Each of the voxels 612 is illustrated as a two-dimensional square; however, it is appreciated that the voxel may be represented as cubes or other shapes in three-dimensional space. It is appreciated that the specific shape and dimensionality of the plurality of voxels 612 may be adjusted dependent on the virtual prototype 606 and photonic device being simulated. It is further noted that only a portion of the plurality of voxels 612 are illustrated to avoid obscuring other aspects of the virtual prototype 606.

Each of the plurality of voxels 612 may be associated with a structural value, a field value, and a source value. Collectively, the structural values of the virtual prototype 606 describe the structural parameters of the photonic device. In one embodiment, the structural values may correspond to a relative permittivity, permeability, and/or refractive index that collectively describe structural (i.e., material) boundaries or interfaces of the photonic device (e.g., material interface pattern 420 of FIG. 4B). For example, an interface 616 is representative of where relative permittivity changes within the virtual prototype 606 and may define a boundary of the photonic device where a first material meets or otherwise interfaces with a second material. The field value describes the field (or loss) response that is calculated (e.g., via Maxwell’s equations) in response to an excitation source described by the source value. The field response, for example, may correspond to a vector describing the electric and/or magnetic fields (e.g., in one or more orthogonal directions) at a particular time step for each of the plurality of voxels 612. Thus, the field response may be based, at least in part, on the structural parameters of the photonic device and the excitation source.

In the illustrated embodiment, the photonic device corresponds to an optical demultiplexer having a design region 614 (e.g., corresponding to dispersive region 332 of FIG. 3A, and/or dispersive region 406 of FIG. 4A), in which structural parameters of the physical device may be updated or otherwise revised. More specifically, through an inverse design process, iterative gradient-based optimization of a loss metric determined from a loss function is performed to generate a design of the photonic device that functionally causes a multi-channel optical signal to be demultiplexed and guided from input port 602 to a corresponding one of the output ports 604. Thus, input port 602 (e.g., corresponding to input region 302 of FIG. 3A, input region 402 of FIG. 4A, and the like) of the photonic device corresponds to a location of an excitation source to provide an output (e.g., a Gaussian pulse, a wave, a waveguide mode response, and the like). The output of the excitation source interacts with the photonic device based on the structural parameters (e.g., an electromagnetic wave corresponding to the excitation source may be perturbed, retransmitted, attenuated, refracted, reflected, diffracted, scattered, absorbed, dispersed, amplified, or otherwise as the wave propagates through the photonic device within virtual prototype 606). In other words, the excitation source may cause the field response of the photonic device to change, which is dependent on the underlying physics governing the physical domain and the structural parameters of the photonic device. The excitation source originates or is otherwise proximate to input port 602 and is positioned to propagate (or otherwise influence the field value of the plurality of voxel) through the design region 614 towards output ports 604 of the photonic device. In the illustrated embodiment, the input port 602 and output ports 604 are positioned outside of the design region 614. In other words, in the illustrated embodiment, only a portion of the structural parameters of the photonic device is optimizable.

However, in other embodiments, the entirety of the photonic device may be placed within the design region 614 such that the structural parameters may represent any portion or the entirety of the design of the photonic device. The electric and magnetic fields within the virtual prototype 606 (and subsequently the photonic device) may change (e.g., represented by the field value of the individual voxel that collectively correspond to the field response of the virtual prototype) in response to the excitation source. The output ports 604 of the optical demultiplexer may be used for determining a performance metric of the photonic device in response to the excitation source (e.g., power transmission from input port 602 to a specific one of the output ports 604). The initial description of the photonic device, including initial structural parameters, excitation sources, performance parameters or metrics, and other parameters describing the photonic device, are received by the system (e.g., design optimization system 500 of FIG. 5) and used to configure the virtual prototype 606 for performing a first-principles based simulation of the photonic device. These specific values and parameters may be defined directly by a user (e.g., of design optimization system 500 in FIG. 5), indirectly (e.g., via controller 512 culling pre-determined values stored in memory 516, local storage 518, or remote resources 510), or a combination thereof.

FIG. 6B illustrates a non-limiting example embodiment of an operational simulation of the photonic device in response to an excitation source within the virtual prototype 608, in accordance with various aspects of the present disclosure. In the illustrated embodiment, the photonic device is an optical demultiplexer structured to optically separate each of a plurality of distinct wavelength channels included in a multi-channel optical signal received at input port 602 and respectively guide each of the plurality of distinct wavelength channels to a corresponding one of the plurality of output ports 604. The excitation source may be selected (randomly or otherwise) from the plurality of distinct wavelength channels and originates at input port 602 having a specified spatial, phase, and/or temporal profile. The operational simulation occurs over a plurality of time steps, including the illustrated time step. When performing the operational simulation, changes to the field response (e.g., the field value) for each of the plurality of voxels 612 are incrementally updated in response to the excitation source over the plurality of time steps. The changes in the field response at a particular time step are based, at least in part, on the structural parameters, the excitation source, and the field response of the virtual prototype 610 at the immediately prior time step included in the plurality of time steps. Similarly, in some embodiments the source value of the plurality of voxels 612 is updated (e.g., based on the spatial profile and/or temporal profile describing the excitation source). It is appreciated that the operational simulation is incremental and that the field values (and source values) of the virtual prototype 610 are updated incrementally at each time step as time moves forward for each of the plurality of time steps during the operational simulation. It is further noted that in some embodiments, the update is an iterative process and that the update of each field and source value is based, at least in part, on the previous update of each field and source value.

Once the operational simulation reaches a steady state (e.g., changes to the field values in response to the excitation source substantially stabilize or reduce to negligible values) or otherwise concludes, one or more performance metrics may be determined. In one embodiment, the performance metric corresponds to the power transmission at a corresponding one of the output ports 604 mapped to the distinct wavelength channel being simulated by the excitation source. In other words, in some embodiments, the performance metric represents power (at one or more frequencies of interest) in the target mode shape at the specific locations of the output ports 604. A loss value or metric of the input design (e.g., the initial design and/or any refined design in which the structural parameters have been updated) based, at least in part, on the performance metric may be determined via a loss function. The loss metric, in conjunction with an adjoint simulation, may be utilized to determine a structural gradient (e.g., influence of structural parameters on loss metric) for updating or otherwise revising the structural parameters to reduce the loss metric (i.e. increase the performance metric). It is noted that the loss metric may be further based on a fabrication loss value that is utilized to enforce a minimum feature size of the photonic device to promote fabricability of the device, and/or other loss values.

FIG. 6C illustrates a non-limiting example embodiment of an adjoint simulation within the virtual prototype 610 by backpropagating a loss metric, in accordance with various aspects of the present disclosure. More specifically, the adjoint simulation is a time-backwards simulation in which a loss metric is treated as an excitation source that interacts with the photonic device and causes a loss response. In other words, an adjoint (or virtual source) based on the loss metric is placed at the output region (e.g., output ports 604) or other location that corresponds to a location used when determining the performance metric. The adjoint source(s) is then treated as a physical stimuli or an excitation source during the adjoint simulation. A loss response of the virtual prototype 608 is computed for each of the plurality of time steps (e.g., backwards in time) in response to the adjoint source. The loss response collectively refers to loss values of the plurality of voxels 612 that are incrementally updated in response to the adjoint source over the plurality of time steps. The change in loss response based on the loss metric may correspond to a loss gradient, which is indicative of how changes in the field response of the physical device influence the loss metric. The fields computed in response to the adjoint source are combined with the fields from the operational simulation to obtain a structural gradient of the photonic device/virtual prototype (e.g., how changes in the structural parameters of the photonic device within the virtual prototype influence the loss metric). Once the structural gradient of a particular cycle (e.g., operational and adjoint simulation) is known, the structural parameters may be updated to reduce the loss metric and generate a revised description or design of the photonic device.

In some embodiments, iterative cycles of performing the operational simulation, and adjoint simulation, determining the structural gradient, and updating the structural parameters to reduce the loss metric are performed successively as part of an inverse design process that utilizes iterative gradient-based optimization. An optimization scheme such as gradient descent may be utilized to determine specific amounts or degrees of changes to the structural parameters of the photonic device to incrementally reduce the loss metric. More specifically, after each cycle the structural parameters are updated (e.g., optimized) to reduce the loss metric. The operational simulation, adjoint simulation, and updating the structural parameters are iteratively repeated until the loss metric substantially converges or is otherwise below or within a threshold value or range such that the photonic device provides the desired performed while maintaining fabricability.

FIG. 7 is a block diagram that illustrates a non-limiting example embodiment of a system according to various aspects of the present disclosure. Overall, the illustrated embodiment of the system 700 is configured to generate proposed segmented designs, to optimize the proposed segmented designs, and to fabricate physical devices based on the proposed segmented designs.

As shown, the system 700 includes a design generation system 702, a fabrication system 704, and a design optimization system 500. Communication between the design generation system 702, the design optimization system 500, and the fabrication system 704 may occur via a network (not pictured), via exchange of a removable computer-readable medium (not pictured), or via any other suitable technique. Though the design generation system 702, fabrication system 704, and design optimization system 500 are illustrated as separate systems, in some embodiments, some portions of these systems may be combined. As one non-limiting example, the design generation system 702 and the design optimization system 500 may be combined in a single system. Also, in some embodiments, systems illustrated in FIG. 7 as a single system may be broken into multiple systems.

In some embodiments, the design generation system 702 may include one or more computing devices that are configured to generate segmented designs that achieve a desired result. For example, the design generation system 702 may use forward simulation and backpropagation techniques to generate a segmented design for an electromagnetic device (or any other type of physical device) that has desired characteristics. This is a non-limiting example only, and any other technique, including but not limited to manual design, may be used by the design generation system 702 to create proposed segmented designs.

In some embodiments, the fabrication system 704 may be any suitable system for fabricating a segmented design. In some embodiments, the fabrication system 704 may be a photolithography system or an additive manufacturing system. In some embodiments, the fabrication system 704 may have characteristics that include a minimum feature size, a minimum feature shape, and/or other constraints that help define the segmented designs that the fabrication system 704 is capable of fabricating. To that end, the fabrication system 704 may provide a design rule checker that is configured to process proposed segmented designs in an inefficient legacy manner to determine whether the proposed segmented designs comply with the constraints of the fabrication system 704.

In some embodiments, the design optimization system 500 may be any suitable computing device or collection of computing devices configured to provide the described functionality of the design optimization system 500 as illustrated and described previously.

While the system 700 described above can be used to generate designs that are highly performant in simulations and physical devices that are reasonably performant, it has been found that differences in the fabrication process used by the fabrication systems 704 to fabricate the designs can lead to changes in the fabricated structures, and therefore changes in the actual performance of the physical devices.

Fabrication models have been developed in order to estimate structures that will be fabricated by a given fabrication process for a given design, and the estimated structures can then be used in the simulations described above to more accurately characterize performance of the as-fabricated design. One challenge that remains is determining a fabrication model that accurately characterizes a given fabrication process. Details of a given fabrication process are often held as trade secrets, and even if the details were known, differences in operating conditions during the fabrication process can lead to different outcomes.

While it is possible to determine characteristics of outputs of the fabrication process by close examination of the fabricated physical devices (e.g., via measurement of images obtained via scanning electron microscopy), this testing is destructive and very time consuming. What is desired are techniques that allow the physical characteristics produced by a fabrication process to be determined by simply measuring performance of a fabricated physical device.

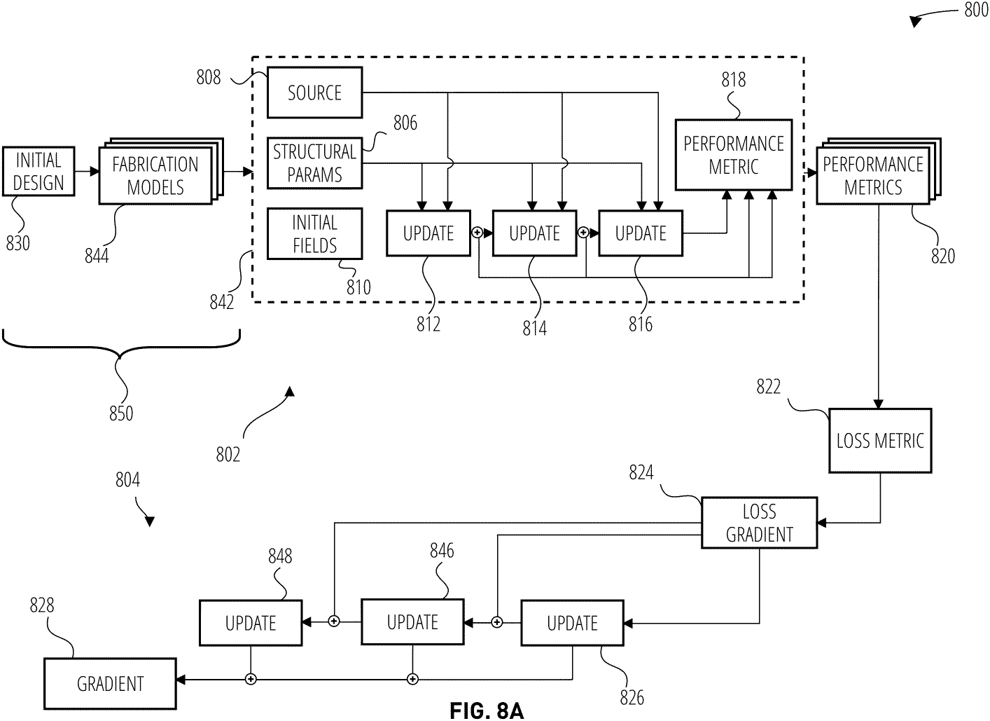

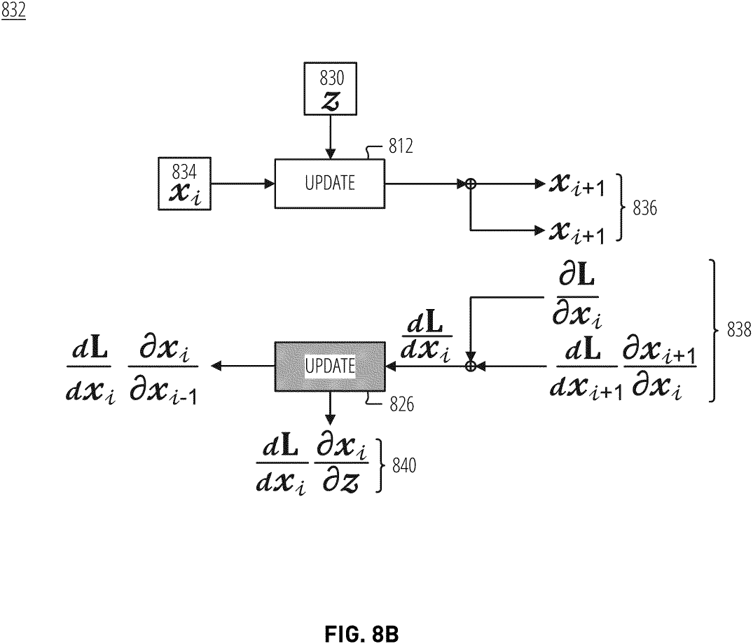

FIG. 8A illustrates a non-limiting example embodiment of a technique for using an inverse design process to determine a design that can be used to fabricate a physical device whose performance corresponds to physical characteristics of the as-fabricated design, and FIG. 8B illustrates the relationship between the operational simulation and the adjoint simulation (backpropagation), according to various aspects of the present disclosure. In the illustrated process, a design is optimized such that, by measuring the output of a physical device fabricated based on the optimized design,

The flow chart 800 shows example time steps for an operational simulation 802 and an adjoint simulation 804, in accordance with various aspects of the present disclosure. Flow chart 800 is one possible implementation that a system may use to perform the operational simulation 802 and adjoint simulation 804 of the virtual prototype describing a photonic integrated circuit (e.g., an optical device operating in an electromagnetic domain such as a photonic demultiplexer). In the illustrated embodiment, the operational simulation 802 utilizes a technique such as a finite-difference time-domain (FDTD) method or a finite-difference frequency-domain (FDFD) method to model the field response (both electric and magnetic) or loss response at each of a plurality of voxels for a plurality of time steps in response to physical stimuli corresponding to an excitation source and/or adjoint source.

In some embodiments, different fabrication models (or different parameters for a single fabrication model) may be used to convert a nominal design to different structural parameters that each closely matches an actual physical device as it would be fabricated given the nominal design and the assumptions embedded in the associated fabrication models. The nominal design may then be optimized using the technique illustrated in the flow chart 800 to maximize differences in performance metrics between the different fabrication models. By creating a physical device that has a measurable performance difference based on the associated fabrication process, the fabrication model that represents the fabrication process can be determined based solely on measurements of performance.

As illustrated in FIG. 8A, the operational simulation 802 includes a configuration portion 850 and a simulation portion 842. In the configuration portion 850, an initial design 830 is received that includes nominal structural parameters for a physical device such as a photonic device to be simulated. In some embodiments, the initial design 830 may also include additional or different information regarding the design, including but not limited to a linear function to define the structural parameters (instead of the structural parameters themselves), desired performance values, a performance loss function to be used to compare simulated performance to desired performance, or other information.

After receiving the initial design 830, the operational simulation 802 uses a plurality of fabrication models 844 to simulate the fabrication of the photonic device based on the initial structural parameters of the initial design 830 to create structural parameters 806 to be simulated in the simulation portion 842 for each fabrication model 844. In some embodiments, each fabrication model 844 is a sequence of differentiable operations that embodies differences from the initial design 830 that will be introduced by a fabrication system during fabrication. In some embodiments, instead of a sequence of differentiable operations, the fabrication model 844 may be represented by a neural network. In some embodiments, parameters for each fabrication model 844 may be learned using an optimization process, or may be specified by a designer to represent differences between different fabrication processes.

In some embodiments, the fabrication models 844 include values for physical characteristics of outputs of a fabrication process performed by a fabrication system, and the different fabrication models 844 use different values. The different values, when used to transform the nominal structural parameters of the initial design 830 into the structural parameters 806 to be simulated, will lead to different simulated performance. The values may represent any aspect of the output of the fabrication process, including but not limited to sidewall angle, layer height, erosion, dilation, structure out of plane, and material imperfections of a material to be processed. For example, a first fabrication model 844 may include a value for a first sidewall angle (i.e., indicating that the fabrication process associated with the first fabrication model 844 generates physical devices with a first sidewall angle) and a second fabrication model 844 may include a value for a second sidewall angle (i.e., indicating that the fabrication process associated with the second fabrication model 844 generates physical devices with a second sidewall angle).

Though illustrated as being different fabrication models 844, one will recognize that in some embodiments, the fabrication models 844 may share an underlying structure (e.g., a mathematical formula, convolutional filter, etc.) but may use different values for parameters to be used with the underlying structure.

After structural parameters 806 are determined for each of the fabrication models 844, the operational simulation 802 proceeds to a simulation portion 842, which is performed for each set of structural parameters 806 / each fabrication model 844. The simulation portion 842 occurs over a plurality of time-steps (e.g., from an initial time step to a final time step over a pre-determined or conditional number of time steps having a specified time step size) and models changes (e.g., from the initial field value 810) in electric and magnetic fields of a plurality of voxels describing the virtual prototype and/or photonic device that collectively correspond to the field response. More specifically, update operations (e.g., update operation 812, update operation 814, and update operation 816) are iterative and based on the field response, structural parameters 806, and one or more excitation sources 808. Each update operation is succeeded by another update operation, which are representative of successive steps forward in time within the plurality of time steps. For example, update operation 814 updates the field values 834 (see, e.g., FIG. 8B) based on the field response determined from the previous update operation 812, excitation sources 808, and the structural parameters 806. Similarly, update operation 816 updates the field values 836 (see, e.g., FIG. 8B) based on the field response determined from update operation 814. In other words, at each time step of the operational simulation 802 the field values (and thus field response) are updated based on the previous field response and structural parameters of the photonic device.

Once the final time step of the simulation portion 842 is performed (although three update operations are illustrated for the sake of clarity and brevity, in some embodiments more than three update operations are performed), a performance metric 818 is used to determine a performance metrics 820 associated with the structural parameters 806, and therefore associated with the fabrication model 844 used to generate the structural parameters 806. In some embodiments, the performance metric 818 is a characterization of the performance of the simulated device at one or more points (e.g., at the output ports of the device) and at one or more bandwidths, similar to the illustration in FIG. 2C.

The performance metric 818 generated for each fabrication model 844 is collected as a set of performance metrics 820, and a loss metric 822 is calculated based on the performance metrics 820. In some embodiments, the loss metric 822 penalizes performance metrics 820 that are similar to each other, and incentivizes performance metrics 820 that are different from each other. Since each of the performance metrics 820 is associated with a different fabrication model 844 (which, in turn, is associated with a different value for a physical characteristic of an output of the fabrication process), this results in the loss metric 822 penalizing performance metrics 820 that are similar for different values of the physical characteristic, and incentivizing performance metrics 820 that are different for different values of the physical characteristic. In this way, performing multiple iterations of the flow chart 800 causes the performance metrics 820 for different values of the physical characteristic to diverge, thus allowing the value of the physical characteristic for an as-fabricated design to be determined by measuring the performance metric of the fabricated physical device.

From the loss metric 822, a loss gradient 824 may be determined. The loss gradient 824 may be treated as adjoint or virtual sources (e.g., physical stimuli or excitation source originating at an output region or port) which are backpropagated in reverse (from the final time step incrementally through the plurality of time steps until reaching the initial time step via update operation 826, update operation 846, and update operation 848) to determine gradient 828. Because it is determined based on the loss metric 822, the gradient 828 is associated with differences between the performance metrics 820 for different fabrication models 844 as discussed above.

In the illustrated embodiment, the FDTD solve (e.g., simulation portion 842 of the operational simulation 802) and backward solve (e.g., adjoint simulation 804) problem are described pictorially, from a high-level, using only “update” and “loss” operations as well as their corresponding gradient operations. The simulation is set up initially in which the structural parameters, physical stimuli (i.e., excitation sources), and initial field states of the virtual prototype (and photonic device) are provided (e.g., via an initial description and/or input design). As discussed previously, the field values are updated in response to the excitation sources based on the structural parameters. More specifically, the update operation is given by ϕ, where xᵢ₊₁ = ϕ(xᵢ, bᵢ,z) for i = 1, ..., n. Here, n corresponds to the total number of time steps (e.g., the plurality of time steps) for the operational simulation, where xᵢ corresponds to the field response (the field value associated with the electric and magnetic fields of each of the plurality of voxels) of the virtual prototype at time step i, bᵢ corresponds to the excitation source(s) (the source value associated with the electric and magnetic fields for each of the plurality of voxels) of the virtual prototype at time step i, and z corresponds to the structural parameters describing the topology and/or material properties of the physical device (e.g., relative permittivity, index of refraction, and the like).

It is noted that using the FDTD method, the update operation may specifically be stated as:

$$\text{ϕ} \left({x}_{i} , {b}_{i} , z\right) = \text{A} \left(z\right) {x}_{i} + \text{B} \left(z\right) {b}_{i}$$

That is to say the FDTD update is linear with respect to the field and source terms. Concretely, A(z) ∈ ℝ^{N×N} and B(z) ∈ ℝ^{N×N} are linear operators which depend on the structural parameters, z, and act on the fields, xᵢ, and the sources, bᵢ, respectively. Here, it is assumed that xᵢ, bᵢ∈ ℝ^{N} where N is the number of FDTD field components in the operational simulation. Additionally, the loss operation (e.g., loss function) may be given by L = f(x₁,..., xₙ), which takes as input the computed fields and produces a single, real-valued scalar (e.g., the loss metric) that can be reduced and/or minimized.

In terms of revising or otherwise optimizing the structural parameters of the physical device, the relevant quantity to produce is

$$\frac{d L}{d z} ,$$

which is used to describe the influence of changes in the structural parameters of the initial design 830 on the loss value and is denoted as the gradient 828 illustrated in FIG. 8A.

FIG. 8B summarizes the operational and adjoint simulation relationships that are involved in computing the structural gradient,

$$\frac{d L}{d z} ,$$

which include

$$\frac{\partial L}{\partial {x}_{i}}$$

$$, \frac{\partial {x}_{i + 1}}{\partial {x}_{i}} , \frac{d L}{d {x}_{i}} , \text{and} \frac{\partial {x}_{i}}{\partial z} .$$

The update operation 814 of the operational simulation 802 updates the field values 834, xᵢ, of the plurality of voxels at the ith time step to the next time step (i.e., i+1 time step), which correspond to the field values 836, xᵢ₊₁. The gradients 838 are utilized to determine

$$\frac{\partial L}{\partial {x}_{i}}$$

for the backpropagation (e.g., update operation 826 backwards in time), which combined with the gradients 840 are used, at least in part, to calculate the structural gradient,

$$\frac{d L}{d z} . \frac{\partial L}{\partial {x}_{i}}$$

is the contribution of each field to the loss metric, L. It is noted that this is the partial derivative, and therefore does not take into account the causal relationship of xᵢ → xᵢ₊₁. Thus,

$$\frac{\partial {x}_{i + 1}}{\partial {x}_{i}}$$

is utilized which encompasses the xᵢ → xᵢ₊₁ relationship. The loss gradient,

$$\frac{d L}{d {x}_{i}} ,$$

may also be used to compute the structural gradient,

$$\frac{d L}{d z}$$

and corresponds to the total derivative of the field with respect to loss value, L. The loss gradient,

$$\frac{d L}{d {x}_{i}} ,$$

at a particular time step, i, isequal to the summation of

$$\frac{\partial L}{\partial {x}_{i}} + \frac{d L}{d {x}_{i + 1}} \frac{\partial {x}_{i + 1}}{\partial {x}_{i}} . \text{Finally,} \frac{\partial {x}_{i}}{\partial z} ,$$

which corresponds to the field gradient, is used which is the contribution to

$$\frac{d L}{d z}$$

from each time/update step.

In particular, the memory footprint to directly compute

$$\frac{\partial L}{\partial {x}_{i}}$$

and

$$\frac{d L}{d z}$$

is so large that it is difficult to store more than a handful of state Tensors. The state Tensor corresponds to storing the values of all of the FDTD cells (e.g., the plurality of voxels) for a single simulation time step. It is appreciated that the term “tensor” may refer to tensors in a mathematical sense or as described by the TensorFlow framework developed by Alphabet, Inc. In some embodiments the term “tensor” refers to a mathematical tensor which corresponds to a multidimensional array that follows specific transformation laws. However, in most embodiments, the term “tensor” refers to TensorFlow tensors, in which a tensor is described as a generalization of vectors and matrices to potentially higher dimensions (e.g., n-dimensional arrays of base data types), and is not necessarily limited to specific transformation laws. For example, for the general loss function f, it may be necessary to store the fields, xᵢ, for all time steps, i. This is because, for most choices of f, the gradient will be a function of the arguments of f. This difficulty is compounded by the fact that the values of

$$\frac{\partial L}{\partial {x}_{i}}$$

for larger values of i are needed before the values for smaller i due to the incremental updates of the field response and/or through backpropagation of the loss metric, which may prevent the use of schemes that attempt to store only the values

$$\frac{\partial L}{\partial {x}_{i}} ,$$

at an immediate time step.

An additional difficulty is further illustrated when computing the structural gradient,

$$\frac{d L}{d z} ,$$

which is given by:

$$\frac{d L}{d z} = {\sum }_{i} \frac{d L}{d {x}_{i}} \frac{\partial {x}_{i}}{\partial z} .$$

For completeness, the full form of the first term in the sum,

$$\frac{d L}{d z} ,$$

is expressed as:

$$\frac{d L}{d {x}_{i}} = \frac{\partial L}{δ {x}_{i}} + \frac{d L}{d {x}_{i + 1}} \frac{\partial {x}_{i + 1}}{\partial {x}_{i}}$$

Based on the definition of ϕ as described by equation (1), it is noted that

$$\frac{\partial {x}_{i + 1}}{\partial {x}_{i}} = A \left(z\right) ,$$

which can be substituted in equation (3) to arrive at an adjoint update for backpropagation (e.g., the update operations such as update operation 826), which can be expressed as:

$$\text{or} \frac{d L}{d {x}_{i}} = \frac{\partial L}{\partial {x}_{i}} + \frac{d L}{d {x}_{i + 1}} A \left(z\right) ,$$

or

$${∇}_{{x}_{i}} L = A {\left(z\right)}^{T} {∇}_{{x}_{i + 1}} L + \frac{\partial {L}^{T}}{\partial {x}_{i}}$$

The adjoint update is the backpropagation of the loss gradient (e.g., from the loss metric) from later to earlier time steps and may be referred to as a backwards solve for

$$\frac{d L}{d {x}_{i}} .$$

More specifically, the loss gradient may initially be based upon the backpropagation of a loss metric determined from the operational simulation with the lossfunction. The second term in the sum of the structural gradient,

$$\frac{d L}{d z} ,$$

corresponds to the field gradient and is denoted as:

$$\frac{\partial {x}_{i}}{\partial z} = \frac{d ϕ \left({x}_{i - 1} , {b}_{i - 1} , z\right)}{d z} = \frac{d A \left(z\right)}{d z} {x}_{i - 1} + \frac{d B \left(z\right)}{d z} {b}_{i - 1} ,$$

for the particular form of ϕ described by the first equation above. Thus, each term of the sum associated

$$\frac{d L}{d z}$$

depends on both

$$\frac{d L}{d {x}_{i}}$$

for i >= i₀ and x_{i₀} for i < i₀. Since the dependency chains of these two terms are in opposite directions, it is concluded that computing

$$\frac{d L}{d z}$$

in this way requires the storage of

$${x}_{i}$$

values for all of i. In some embodiments, the need to store all field value may be mitigated by a reduced representation of the fields.

Returning to FIG. 8A, the operational simulation 802 and adjoint simulation 804 as described above are used to optimize the initial design 830 with respect to a loss metric 822.

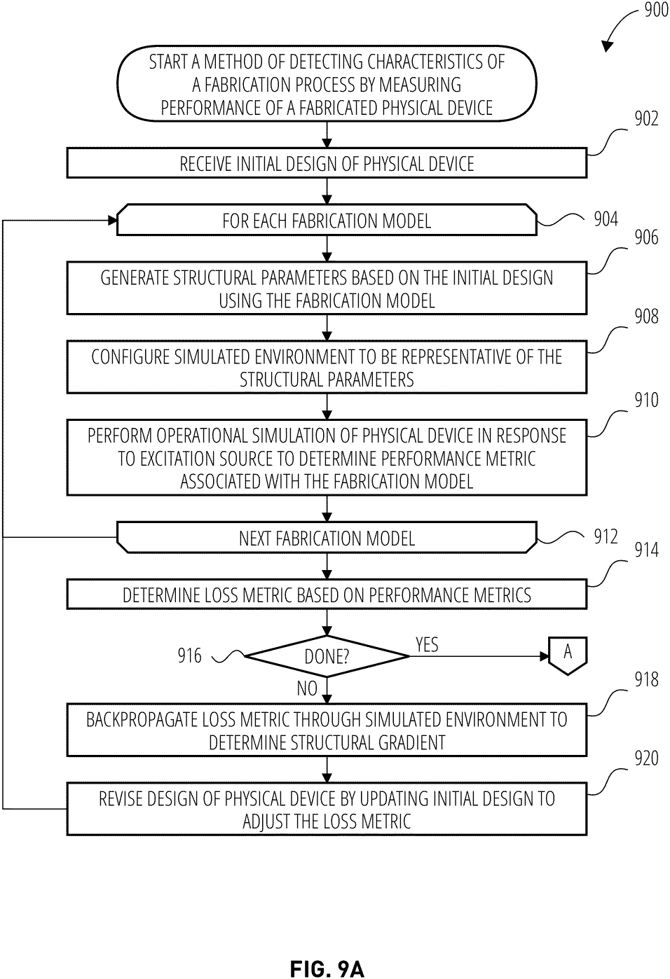

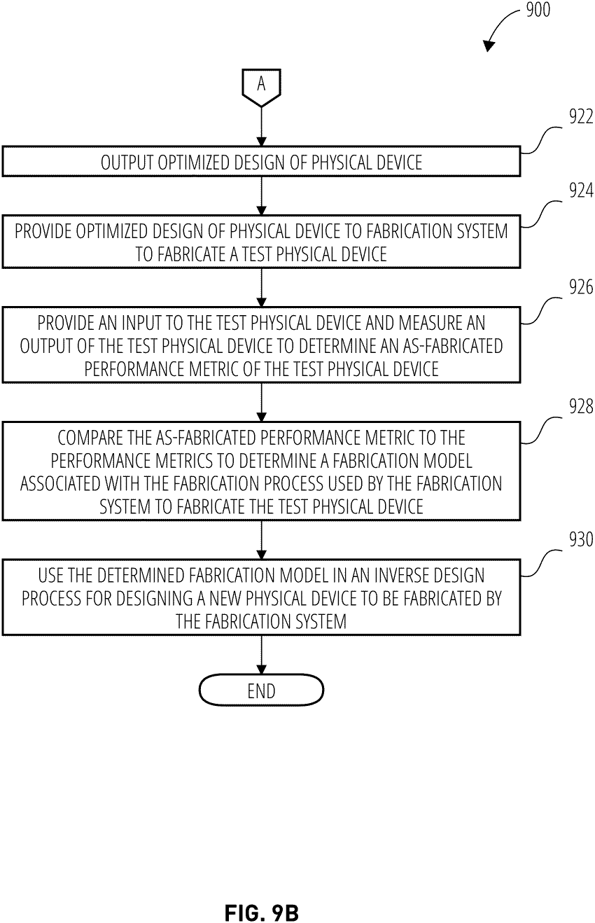

FIG. 9A and FIG. 9B are a flowchart that illustrates a non-limiting example embodiment of a method of detecting characteristics of a fabrication process by measuring performance of a fabricated physical device, in accordance with various aspects of the present disclosure. It is appreciated that method 900 uses an optimization process as illustrated in FIG. 8A and FIG. 8B that may be accomplished by performing operations with a system (e.g., design optimization system 500 of FIG. 5) to perform iterative gradient-based optimization of using a loss metric that penalizes similar performance by dissimilar fabrication processes. In the same or other embodiments, method 900 may be included as instructions and/or logic provided by at least one machine-accessible storage medium (e.g., non-transitory memory) that, when executed by a machine, will cause the machine to perform operations for generating and/or improving the design of the physical device/photonic integrated circuit. It is further appreciated that the order in which some or all of the process blocks appear in method 900 should not be deemed limiting. Rather, one of ordinary skill in the art having the benefit of the present disclosure will understand that some of the process blocks may be executed in a variety of orders not illustrated, or even in parallel.

From a start block, the method 900 proceeds to block 902, where an initial design of a physical device such as a photonic integrated circuit is received. In some embodiments, the physical device may be expected to be used to measure one or more physical characteristics of the fabrication process, and the initial design provided to the method 900 may include indications of one or more output ports to be associated with each of the one or more physical characteristics. In some embodiments, the initial design may indicate a wavelength or wavelength band to be swept as an operational input to the physical device during testing.

In some embodiments, the initial design may describe structural parameters of the physical device within a simulated environment. The simulated environment may include a plurality of voxels that collectively describe the structural parameters of the physical device. Each of the plurality of voxels is associated with a structural value to describe the structural parameters, a field value to describe the field response (e.g., the electric and magnetic fields in one or more orthogonal directions) to physical stimuli (e.g., one or more excitation sources), and a source value to describe the physical stimuli. In some embodiments the initial design may be a first description of the physical device in which values for the structural parameters may be random values or null values outside of the periphery region such that there is no bias for the initial (e.g., first) design.

It is appreciated that the initial description or input design may be a relative term. Thus, in some embodiments an initial description may be a first description of the physical device described within the context of the simulated environment (e.g., a first input design for performing a first operational simulation). However, in other embodiments, the term initial description may refer to an initial description of a particular cycle (e.g., of performing an operational simulation, operating an adjoint simulation, and updating the structural parameters and/or locations of one or more ports). In such an embodiment, the initial design or design of that particular cycle may correspond to a revised description or refined design (e.g., generated from a previous cycle).

In some embodiments, the simulated environment includes a design region that includes a portion of the plurality of voxels which have structural parameters that may be updated, revised, or otherwise changed to optimize the structural parameters of the physical device. In the same or other embodiments, the structural parameters are associated with geometric boundaries and/or material compositions of the physical device based on the material properties (e.g., relative permittivity, index of refraction, etc.) of the simulated environment.

The method 900 then proceeds to a for-loop defined between a for-loop start block 904 and a for-loop end block 912, wherein operational simulations of the physical device are performed for two or more fabrication models 844 are determined. Each fabrication model of the fabrication models 844 represents at least one different physical characteristic of an output of a fabrication process. In some embodiments, two or more of the fabrication models 844 use a shared mathematical architecture but have different parameter values. In some embodiments, two or more of the fabrication models 844 use different mathematical architectures as well as or instead of different parameter values. As a non-limiting example, a first fabrication model 844 may specify a first value for a sidewall angle, and a second fabrication model 844 may specify a second value for a sidewall angle. Sidewall angle is a non-limiting example of a value for a physical characteristic that may be represented. Other examples include, but are not limited to, layer heights, erosion, dilation, structure out of plane, and material imperfections of a material to be processed.

From the for-loop start block 904, the method 900 proceeds to process the first fabrication model 844 at block 906, where structural parameters based on the initial design are generated using the fabrication model 844. The fabrication model 844 is used to transform the structural parameters of the initial design into structural parameters that would be predicted to be generated using the fabrication process, and may use any suitable technique, including but not limited to convolving the initial design with a filter associated with the fabrication model 844.

At block 908, a simulated environment is configured to be representative of the structural parameters. In some embodiments, the simulated environment is configured (e.g., the number of voxels, shape/arrangement of voxels, and specific values for the structural value, field value, and/or source value of the voxels are set based on the structural parameters).

In some embodiments the simulated environment includes a design region optically coupled between a first communication region and one or more second communication regions. In some embodiments, the first communication region may correspond to an input region or port (e.g., where an excitation source originates), while the second communication region may correspond to one or more output regions or ports (e.g., when designing a physical device where an output may be measured to determine the physical characteristics of the fabrication process). However, in other embodiments, the first communication region may correspond to an output region or port, while the plurality of second communication regions corresponds to a plurality of input ports or region.

Block 910 illustrates performing an operational simulation of the physical device within the simulated environment operating in response to one or more excitation sources to determine a performance metric associated with the fabrication model 844. More specifically, in some embodiments an electromagnetic simulation is performed in which a field response of the photonic integrated circuit is updated incrementally over a plurality of time steps to determine how the field response of the physical device changes due to the excitation source. The field values of the plurality of voxels are updated in response to the excitation source and based, at least in part, on the structural parameters of the integrated photonic circuit. Additionally, each update operation at a particular time step may also be based, at least in part, on a previous (e.g., immediately prior) time step.

Consequently, the operational simulation simulates an interaction between the photonic device (i.e., the photonic integrated circuit) and a physical stimuli (i.e., one or more excitation sources) to determine a simulated output of the photonic device (e.g., at one or more of the output ports or regions) in response to the physical stimuli. The interaction may correspond to any one of, or combination of a perturbation, retransmission, attenuation, dispersion, refraction, reflection, diffraction, absorption, scattering, amplification, or otherwise of the physical stimuli within electromagnetic domain due, at least in part, to the structural parameters of the photonic device and underlying physics governing operation of the photonic device. Thus, the operational simulation simulates how the field response of the simulated environment changes due to the excitation source over a plurality of time steps (e.g., from an initial to final time step with a pre-determined step size).

In some embodiments, the simulated output may be utilized to determine one or more performance metrics of the physical device. For example, the excitation source may be light of one or more wavelengths specified by the initial design. The excitation source may originate at or be disposed proximate to the first communication region (i.e., a port designated as the input port) when performing the operational simulation. During the operational simulation, the field response at one or more output ports may then be utilized to determine a simulated power transmission of the photonic integrated circuit for the one or more wavelengths received by the input port. In other words, the operational simulation may be utilized to determine the performance metric that includes determining a simulated power transmission of the excitation source from the first communication region/port, through the design region, and to one or more second communication regions/ports.

In some embodiments, the excitation source may cover a wide spectrum, and simulated power transmission to a given output port in a given band may be associated with a specific physical characteristic. As such, simulated power transmission at the given output port in the given band may be used to determine the performance metric. In some embodiments, simulated power transmission to different output ports at the same or different wavelength bands may indicate different physical characteristics. In some embodiments, a comparison of power transmission between different output ports at a given wavelength band may be associated with a performance metric indicating a single physical characteristic. In some embodiments, the performance metric is stored in association with the fabrication model 844, such that a measurement of the performance metric in a fabricated physical device can be associated with the fabrication model 844, as described below.

Once a performance metric has been determined for the fabrication model 844, the method 900 proceeds to for-loop end block 912. If further fabrication models 844 remain to be processed, then the method 900 returns to for-loop start block 904 to process the next fabrication model 844. Otherwise, the method 900 proceeds to block 914.

Block 914 shows determining a loss metric based on the performance metrics. As discussed above, the loss metric compares the performance metrics, penalizing performance metrics that are similar for different values of physical characteristics/different fabrication models 844 associated with the different values of the physical characteristics, and rewarding performance metrics that are dissimilar for different values of physical characteristics/different fabrication models 844 associated with the different values of the physical characteristics. For example, if a performance metric for a first sidewall angle is similar to a performance metric for a second sidewall angle, then the loss metric would penalize these two performance metrics. Likewise, if a performance metric for the first sidewall angle is different from a performance metric for a second sidewall angle, then the loss metric would reward these two performance metrics.

The method 900 then proceeds to a decision block 916, where a determination is made as to whether further iterations of the update of the initial design are to be processed. In some embodiments, the determination is based on whether the loss metric has converged to a global or local minimum value (i.e., the loss metric is not improving after two or more iterations of updating of the initial design). In some embodiments, the determination is based on whether the loss metric has reached a threshold value that indicates usable performance. In some embodiments, the determination is based on whether a predetermined number of update iterations have been performed.

If it is determined that further update iterations are desired, then the result of decision block 916 is NO, and the method 900 proceeds to block 918. Block 918 illustrates backpropagating the loss metric via the loss function through the simulated environment to determine an influence of changes in the structural parameters on the loss metric (i.e., structural gradient). The loss metric is treated as an adjoint or virtual source and is backpropagated incrementally from a final time step to earlier time steps in a backwards simulation to determine the structural gradient of the physical device.

Block 920 shows revising a design of the physical device (e.g., generated a revised description) by updating the initial design (e.g., structural parameters indicated by the initial design) to adjust the loss metric and thereby create an updated design. In some embodiments, adjusting for the loss metric may reduce the loss metric. However, in other embodiments, the loss metric may be adjusted or otherwise compensated in a manner that does not necessarily reduce the loss metric, In one embodiment, adjusting the loss metric may provide a general direction within the parameterization space to obtain designs that will ultimately result in increased performance while also maintaining device fabricability and targeted performance metrics. In some embodiments, the updated initial design is generated by utilizing an optimization scheme after a cycle of operational and adjoint simulations via a gradient descent algorithm, Markov Chain Monte Carlo algorithm, or other optimization techniques. After updating the initial design at block 920, the method 900 returns to for-loop start block 904 to conduct a subsequent iteration of the optimization process and further improve the updated design.

Returning to decision block 916, if it is determined that further update iterations are not desired, then the result of decision block 916 is YES, and the method 900 proceeds to a continuation terminal (“terminal A”). From terminal A (FIG. 9B), the method 900 proceeds to block 922 where the optimized design of a physical device is output. In some embodiments, the optimized design may be saved on a computer-readable medium by the design optimization system 500 for later use.

Block 924 shows providing the optimized design of the physical device to a fabrication system 704 to fabricate a test physical device. The fabrication system 704 then fabricates the test physical device based on the optimized design. In some embodiments, the optimized design may be included with various other designs to be concurrently fabricated by the fabrication system 704 (e.g., multiple devices fabricated on a single wafer), and performance of the test physical device may be tested as described below to determine the physical characteristics of all of the devices fabricated on the same wafer.

Block 926 shows providing an input to the test physical device and measuring an output of the test physical device to determine an as-fabricated performance metric of the test physical device. For example, one or more ranges of frequencies may be swept in an input provided to the input port of the test physical device, and the as-fabricated performance metric may indicate output power at one or more of the frequencies for one or more output ports.

Block 928 shows comparing the as-fabricated performance metric to the performance metrics measured within the flow chart 800 to determine a fabrication model associated with the fabrication process used by the fabrication system 704 to fabricate the test physical device. As discussed above, the simulated performance metrics may be stored in association with the fabrication models 844. By comparing the stored performance metrics with the as-fabricated performance metric to determine which of the stored performance metrics the as-fabricated performance metric resembles, the associated fabrication model 844 can be determined. In some embodiments, a peak wavelength of the as-fabricated performance metric may be determined, and a stored performance metric with a closest peak wavelength may be identified as the matching stored performance metric, and the fabrication model 844 associated with that stored performance metric may be identified as the determined fabrication model 844.

Once the fabrication model 844 is determined, the fabrication model 844 may be used for any suitable purpose. As a non-limiting example, block 930 shows using the determined fabrication model 844 in an inverse design process for designing a new physical device to be fabricated by the fabrication system 704. The inverse design process may be similar to the process illustrated in the flow chart 800, but instead of using multiple fabrication models 844 and optimizing a loss metric that maximizes the differences in performance between the fabrication models 844, the determined fabrication model 844 can be used along with a loss metric that penalizes differences in performance between the simulated performance metric and a desired performance metric specified in an initial design (e.g., desired wavelength response characteristics for one or more output ports for an optical demultiplexer, etc.). By using the determined fabrication model 844, the simulation of the new physical device more accurately matches the structure that would be fabricated for the new physical device by the fabrication system 704, and the performance and reliability of the new physical device is therefore improved.

The method 900 then proceeds to an end block and terminates.

The description above primarily relates to designing a test physical device for which output measured at an output port represents a physical characteristic of outputs of the fabrication process. In some embodiments, outputs of multiple output ports may be combined to represent the physical characteristic. In some embodiments, the test physical device may be designed to include multiple output ports, and each output port may represent a different physical characteristic (e.g., a performance metric of a first output port represents a sidewall angle, a performance metric of a second output port represents a layer height, etc.). In such embodiments, the loss metric 822 may include separate terms for each output port, such that all of the output ports can be concurrently optimized. In some embodiments, the process illustrated in the flow chart 800 may be used to design multiple test physical devices, with each separate test physical device intended to measure one or more different physical characteristics.

In the preceding description, numerous specific details are set forth to provide an understanding of various embodiments of the present disclosure. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The order in which some or all of the blocks appear in each method flowchart should not be deemed limiting. Rather, one of ordinary skill in the art having the benefit of the present disclosure will understand that actions associated with some of the blocks may be executed in a variety of orders not illustrated, or even in parallel.

The processes explained above are described in terms of computer software and hardware. The techniques described may constitute machine-executable instructions embodied within a tangible or non-transitory machine (e.g., computer) readable storage medium, that when executed by a machine will cause the machine to perform the operations described. Additionally, the processes may be embodied within hardware, such as an application specific integrated circuit (“ASIC”) or otherwise.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. A non-transitory computer-readable medium having computer-executable instructions stored thereon that, in response to execution by one or more processors of a computing system, cause the computing system to perform actions for optimizing a test physical device for detecting physical characteristics of outputs of a fabrication process, the actions comprising:
simulating, by the computing system, fabrication of an initial design for the test physical device using at least a first fabrication model to determine first structural parameters and a second fabrication model to determine second structural parameters, wherein the first fabrication model assumes a first value for a physical characteristic of outputs of the fabrication process, and wherein the second fabrication model assumes a second value for the physical characteristic of outputs of the fabrication process;
obtaining at least a first performance metric by simulating performance of the first structural parameters;
obtaining at least a second performance metric by simulating performance of the second structural parameters;
determining a loss metric based on at least the first performance metric and the second performance metric, wherein the loss metric penalizes performance metrics with similar values for dissimilar structural parameters; and
backpropagating a gradient of the loss metric to generate an updated design.

2. The non-transitory computer-readable medium of claim 1, wherein the actions further comprise repeating the simulating, obtaining, determining, and backpropagating actions two or more times.

3. The non-transitory computer-readable medium of claim 1, wherein the actions further comprise providing the updated design to a fabrication system to fabricate the test physical device using the fabrication process.

4. The non-transitory computer-readable medium of claim 3, wherein the actions further comprise:
receiving a measurement of an as-fabricated performance metric of the test physical device; and
determining, based on the measurement of the as-fabricated performance metric of the test physical device, whether the fabrication system is associated with the first value of the physical characteristic or the second value of the physical characteristic.

5. The non-transitory computer-readable medium of claim 4, wherein the measurement of the as-fabricated performance metric includes a measurement of light at an output port of the test physical device.

6. The non-transitory computer-readable medium of claim 4, wherein the first value and the second value are sidewall angles, layer heights, erosion, dilation, structure out of plane, and material imperfections of a material to be processed.

7. The non-transitory computer-readable medium of claim 1, wherein the initial design includes a first output port and a second output port;
wherein obtaining at least the first performance metric includes obtaining the first performance metric and a third performance metric;
wherein obtaining at least the second performance metric includes obtaining the second performance metric and a fourth performance metric;
wherein the first performance metric and the second performance metric are associated with the first output port; and
wherein the third performance metric and the fourth performance metric are associated with the second output port.

8. The non-transitory computer-readable medium of claim 7, wherein determining the loss metric based on at least the first performance metric and the second performance metric includes:
determining the loss metric based on at least the first performance metric, the second performance metric, the third performance metric, and the fourth performance metric;
wherein the loss metric penalizes similar values for the first performance metric and the second performance metric for dissimilar values of the first physical characteristic of outputs of the fabrication system; and
wherein the loss metric penalizes similar values for the third performance metric and the fourth performance metric for dissimilar values of a second physical characteristic of outputs of the fabrication system.

9. A computer-implemented method for optimizing a test physical device for detecting variations in a fabrication process, the method comprising:
simulating, by a computing system, fabrication of an initial design for the test physical device using at least a first fabrication model to determine first structural parameters and a second fabrication model to determine second structural parameters, wherein the first fabrication model assumes a first value for a physical characteristic of outputs of the fabrication process, and wherein the second fabrication model assumes a second value for the physical characteristic of outputs of the fabrication process;
obtaining, by the computing system, at least a first performance metric by simulating performance of the first structural parameters;
obtaining, by the computing system, at least a second performance metric by simulating performance of the second structural parameters;
determining, by the computing system, a loss metric based on at least the first performance metric and the second performance metric, wherein the loss metric penalizes performance metrics with similar values for dissimilar structural parameters; and
backpropagating, by the computing system, a gradient of the loss metric to generate an updated design.

10. The computer-implemented method of claim 9, wherein the actions further comprise repeating the simulating, obtaining, determining, and backpropagating actions two or more times.

11. The computer-implemented method of claim 9, wherein the method further comprises providing the updated design to a fabrication system to fabricate the test physical device using the fabrication process.

12. The computer-implemented method of claim 11, wherein the method further comprises:
receiving a measurement of an as-fabricated performance metric of the test physical device; and
determining, based on the measurement of the as-fabricated performance metric of the test physical device, whether the fabrication system is associated with the first value of the physical characteristic or the second value of the physical characteristic.

13. The computer-implemented method of claim 12, wherein the measurement of the as-fabricated performance metric includes a measurement of light at an output port of the test physical device.

14. The computer-implemented method of claim 12, wherein the first value and the second value are sidewall angles, layer heights, erosion, dilation, structure out of plane, and material imperfections of a material to be processed.

15. The computer-implemented method of claim 9, wherein the initial design includes a first output port and a second output port;
wherein obtaining at least the first performance metric includes obtaining the first performance metric and a third performance metric;
wherein obtaining at least the second performance metric includes obtaining the second performance metric and a fourth performance metric;
wherein the first performance metric and the second performance metric are associated with the first output port; and
wherein the third performance metric and the fourth performance metric are associated with the second output port.

16. The computer-implemented method of claim 15, wherein determining the loss metric based on at least the first performance metric and the second performance metric includes:
determining the loss metric based on at least the first performance metric, the second performance metric, the third performance metric, and the fourth performance metric;
wherein the loss metric penalizes similar values for the first performance metric and the second performance metric for dissimilar values of the first physical characteristic of outputs of the fabrication system; and
wherein the loss metric penalizes similar values for the third performance metric and the fourth performance metric for dissimilar values of a second physical characteristic of outputs of the fabrication system.

17. A method of determining a physical characteristic of physical devices fabricated by a fabrication system, the method comprising:
providing a design for a test physical device to the fabrication system to fabricate the test physical device;
applying light from a light source to an input port of the test physical device;
measuring light output from an output port of the test physical device to determine a performance metric;
comparing the performance metric to simulated performance metrics associated with fabrication models that represent different physical characteristics; and
determining the physical characteristic based on the comparison of the performance metric to the simulated performance metrics.

18. The method of claim 17, wherein the physical characteristic is a sidewall angle, a layer height, an amount of erosion, an amount of dilation, a structure out of plane, or material imperfections of a material to be processed.

19. The method of claim 17, further comprising:
measuring light output from a second output port of the test physical device to determine a second performance metric; and
comparing the second performance metric to the simulated performance metrics associated with fabrication models that represent different physical characteristics; and
determining a second physical characteristic based on the comparison of the second performance metric to the simulated performance metrics.

20. The method of claim 17, further comprising:
using a fabrication model associated with the determined physical characteristic to design a new physical device.
